(19) United States
(12) Patent Application Publication
(10) Pub. No.: US 2025/0364311 A1
(43) Pub. Date: Nov. 27, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventor: Tzu-Ging LIN, Kaohsiung City (TW)

(21) Appl. No.: 19/292,991

(22) Filed: Aug. 7, 2025

Related U.S. Application Data
(63) Continuation of application No. 18/644,188, filed on Apr. 24, 2024.
(60) Provisional application No. 63/615,688, filed on Dec. 28, 2023.

(51) Int. Cl. H01L 21/762; H10D 30/01; H10D 30/43; H10D 30/67; H10D 62/10; H10D 64/01; H10D 64/23

(52) U.S. Cl. CPC H01L 21/76224; H10D 30/014; H10D 30/43; H10D 30/6729; H10D 30/6735; H10D 30/6757; H10D 62/121; H10D 64/01; H10D 64/254

(57) ABSTRACT

A semiconductor device structure is described. The structure includes a fin structure formed on a substrate, a source/drain feature disposed adjacent the fin structure and over the substrate, wherein a top surface of the source/drain feature and a front side of the substrate are substantially co-planar, an isolation trench extending from the front side of the substrate towards a backside of the substrate, and a backside via contact extending from the backside of the substrate towards and in contact with the source/drain feature, wherein the backside via contact and the isolation trench are parallelly arranged and separated from each other by a constant gap along boundaries of the backside via contact and the isolation trench.

### CROSS-REFERENCE TO RELATED APPLICATIONS

This application is a continuation application of U.S. patent application Ser. No. 18/644,188 filed Apr. 24, 2024, which claims priority to U.S. Provisional Application Ser. No. 63/615,688 filed Dec. 28, 2023, which is incorporated by reference in their entirety.

### BACKGROUND

As the semiconductor industry has progressed into nanometer technology process nodes in pursuit of higher device density, higher performance, and lower costs, challenges from both fabrication and design issues have resulted in the development of multi-gate devices, such as fin field-effect transistors (FinFETs) and gate-all-around (GAA) transistors. To continue to provide the desired scaling and increased density for multi-gate devices in advanced technology nodes, continued reduction of the gate pitch is necessary. Various schemes, such as poly on diffusion edge (PODE) and continuous poly on diffusion edge (CPODE), have been used to scale the gate pitch while preventing leakage current between transistors. However, such schemes cannot provide the etch profile required for aggressively scaled circuits and devices, especially when it comes to the back side power rail application.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure in accordance with some embodiments.

FIGS. 7A-11A are cross-sectional side views of various stages of manufacturing the semiconductor device structure taken along cross-section A-A of FIG. 6, in accordance with some embodiments.

FIGS. 7B-11B are cross-sectional side views of various stages of manufacturing the semiconductor device structure taken along cross-section B-B of FIG. 6, in accordance with some embodiments.

FIGS. 7C-11C are cross-sectional side views of various stages of manufacturing the semiconductor device structure taken along cross-section C-C of FIG. 6, in accordance with some embodiments.

FIGS. 12A-12B to 21A-21B and 23A-23B to 40A-40B are cross-sectional side views of one of various stages of manufacturing the semiconductor device structure of FIGS. 11A and 11B showing multiple fin structures disposed along the X and Y directions, respectively, in accordance with some embodiments.

FIGS. 22A-22G illustrate an exemplary cyclic etch process for forming an isolation trench in accordance with some embodiments.

FIG. 28A-1 illustrates an enlarged view of a portion of the semiconductor device structure shown in FIG. 28A, in accordance with some embodiments.

FIGS. 41A-41C illustrate a schematic view of a region of the semiconductor device structure in FIG. 40A showing various arrangements of an isolation trench (CPODE) structure and a backside via contact in accordance with some embodiments.

FIGS. 42A and 42B are cross-sectional views of the semiconductor device structure showing the isolation trench structure and the backside via contact arranged in accordance with the embodiment shown in FIG. 41B.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As integrated circuit scales down, epitaxial critical dimension (EPI CD), which refers to spacings between epitaxial regions, becomes smaller and smaller. Small EPI CD makes it challenging to etch trenches for insulation structures without damaging adjacent structures, such as epitaxial source/drain features. Exemplary insulation structures may include a Continuous-Poly-On-Diffusion-Edge (CPODE) structure that removes a portion of, or a selected fin structure in its entirety, and replaces with it with an insulating material to form isolation trenches. The CPODE structures avoid leakage current through epitaxial source/drain features, transistors, and silicon substrates. Embodiments of the present disclosure provide an improved etch process for forming high aspect ratio CPODE structures with a straight sidewall profile, which facilitates a back side power rail application.

While the embodiments of the present disclosure describe a CPODE-first processing methods, i.e., during front-end-of-line (FEOL) processing before metal gate formation, the embodiments are equally applicable to a CPODE-last processing method (or so-called CMODE process), i.e., during middle-end-of-line (MEOL) processing after metal gate formation is formed. The embodiments of the present disclosure are also applicable to other devices which may include CPODE or CMODE structures, such as planar FETs, Fin-FETs, Horizontal Gate All Around (HGAA) FETs, Vertical Gate All Around (VGAA) FETs, and other suitable devices.

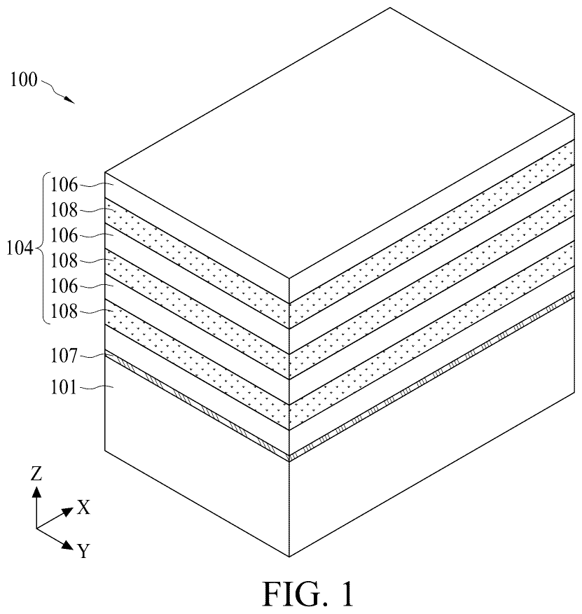

FIGS. 1 to 42B show exemplary processes for manufacturing a semiconductor device structure 100 according to embodiments of the present disclosure. It is understood that additional operations can be provided before, during, and after processes shown by FIGS. 1 to 42B, and some of the operations described below can be replaced or eliminated, for additional embodiments of the method. The order of the operations/processes is not limiting and may be interchangeable.

The semiconductor device structure 100 generally includes a stack of semiconductor layers 104 disposed over a substrate 101. The substrate 101 may include various regions that have been doped with impurities (e.g., dopants having p-type or n-type impurities). Depending on circuit design, the dopants may be, for example boron for p-type field effect transistors (p-type FETs) and phosphorus for n-type field effect transistors (n-type FETs).

The stack of semiconductor layers 104 includes alternating semiconductor layers made of different materials to facilitate formation of nanosheet channels in a multi-gate device, such as nanosheet channel FETs. In some embodiments, the stack of semiconductor layers 104 includes first semiconductor layers 106 and second semiconductor layers 108 vertically stacked over the substrate 101. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanosheet channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. The semiconductor device structure 100 may include a nanosheet transistor. The nanosheet transistors may be referred to as nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

In some embodiments, a sacrificial layer 107 may be formed between the substrate 101 and the stack of semiconductor layers 104. The sacrificial layer 107 serves as an etch stop layer to prevent damaging to epitaxial source/drain features during the wafer thinning process for back side power rail application. The material of the sacrificial layer 107 is chosen such that the sacrificial layer 107 has a different etch selectivity with respect to the material of the substrate 101. In various embodiments, the sacrificial layer 107 may be a silicon germanium (SiGe) layer. The SiGe layer may be a single crystal SiGe layer, a graded SiGe layer where a germanium concentration varies with the distance from the interface of the graded SiGe layer with the exposed substrate 101, or a non-graded SiGe where a germanium concentration does not vary with the distance from the interface of the non-graded SiGe layer with the exposed substrate. In some cases, the SiGe layer can have a germanium composition percentage between about 50% and 95%. Other materials, such as silicon carbide, silicon nitride, may also be used.

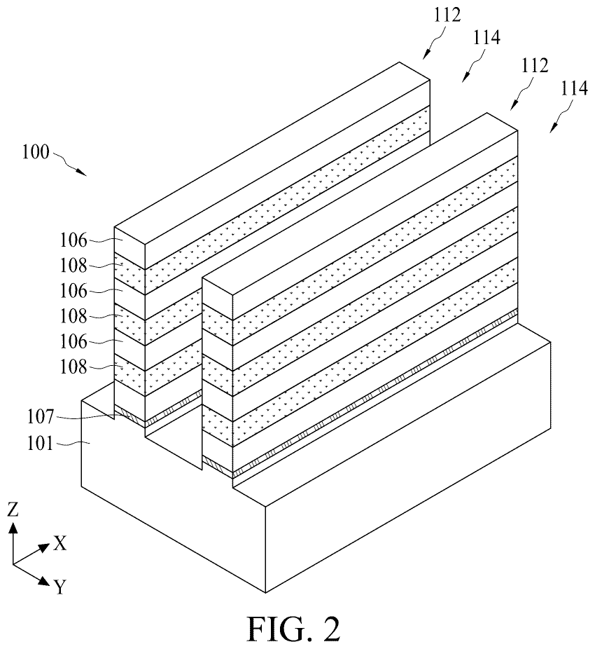

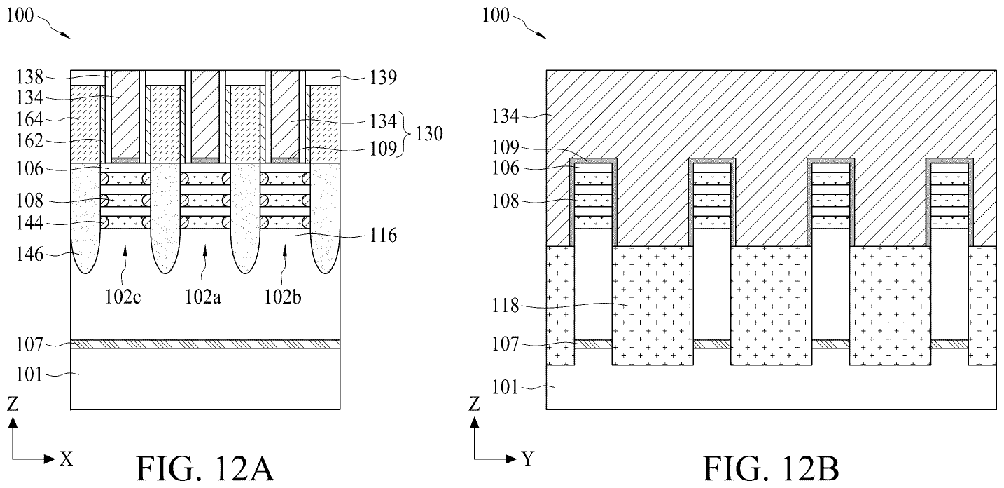

In FIG. 2, fin structures 112 are formed from the stack of semiconductor layers 104. Each fin structure 112 has an upper portion including the semiconductor layers 106, 108 and the sacrificial layer 107, and a well portion (not shown) formed from the substrate 101. The fin structures 112 may be formed by patterning a hard mask layer (not shown) formed on the stack of semiconductor layers 104 using multi-patterning operations including photolithography and etching processes. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof. As shown in FIG. 2, two fins are formed, but the number of the fins is not limited to two. Three or more fins are arranged along the X direction in some embodiments, as shown in FIGS. 12A-12B to 42A-42B.

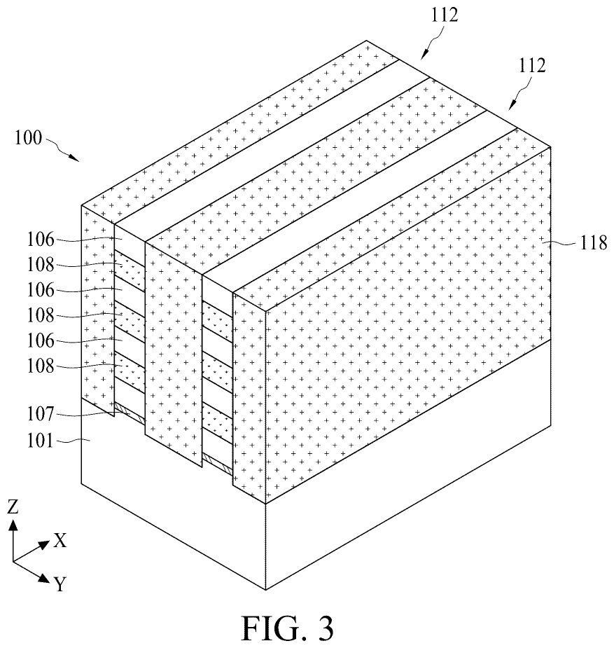

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

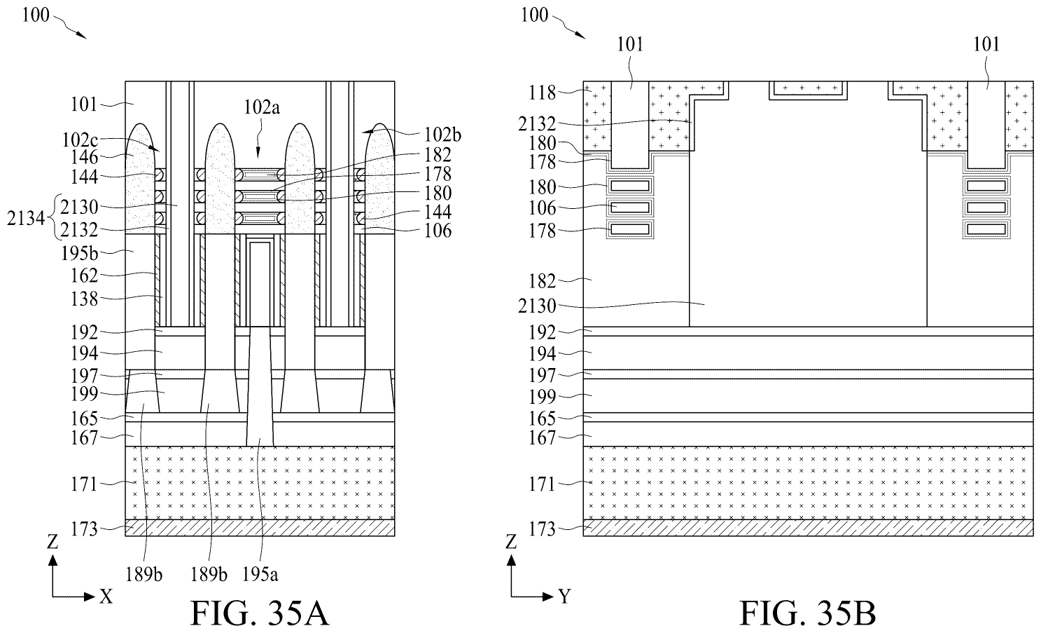

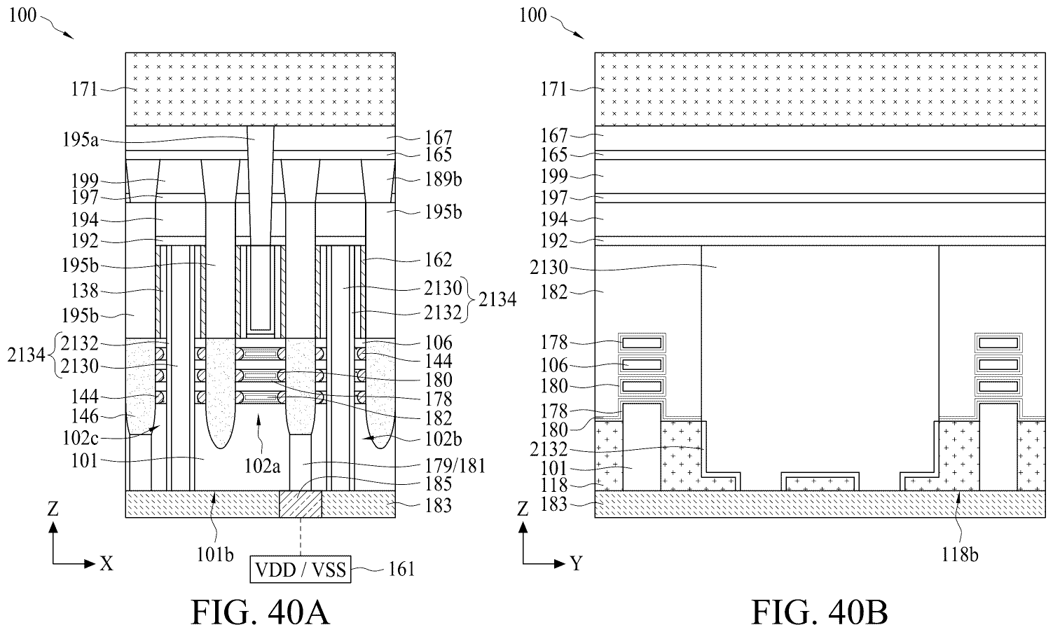

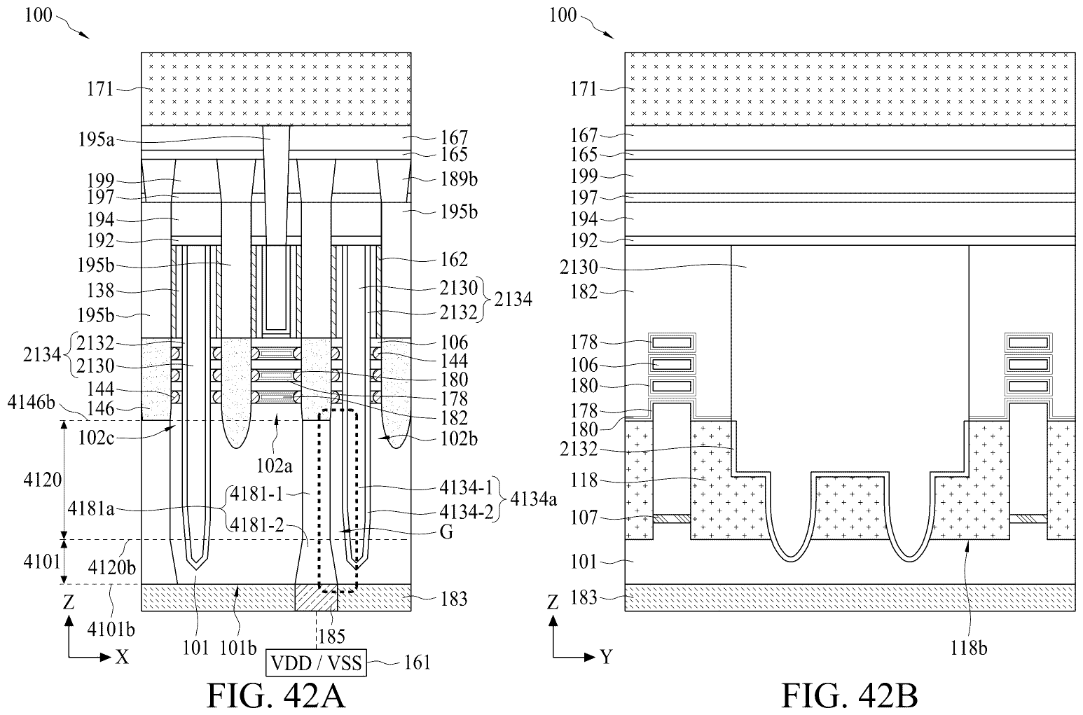

Depending on the application, the position of the sacrificial layer 107 may be changed relative to a bottom 118b of the insulating material 118 to control the amount of the substrate 101 to be removed during the grinding process (FIGS. 35A and 35B). If the sacrificial layer 107 is disposed at an elevation above the bottom 118b of the insulating material 118, a greater amount of the substrate 101 will be removed, resulting in a thinner substrate 101, such as an embodiment shown in FIGS. 40A and 40B. On the other hand, if the sacrificial layer 107 is disposed at an elevation below the bottom 118b of the insulating material 118, the amount of the substrate 101 to be removed will be less, resulting in a thicker substrate 101, such as an embodiment shown in FIGS. 42A and 42B.

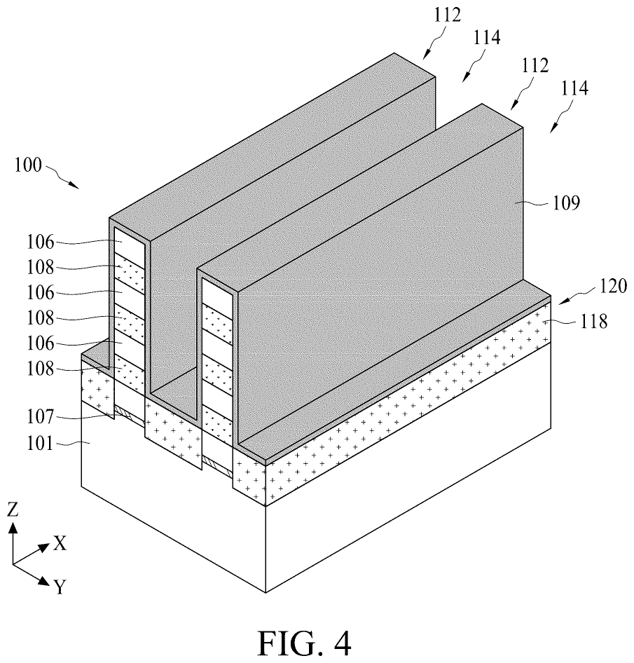

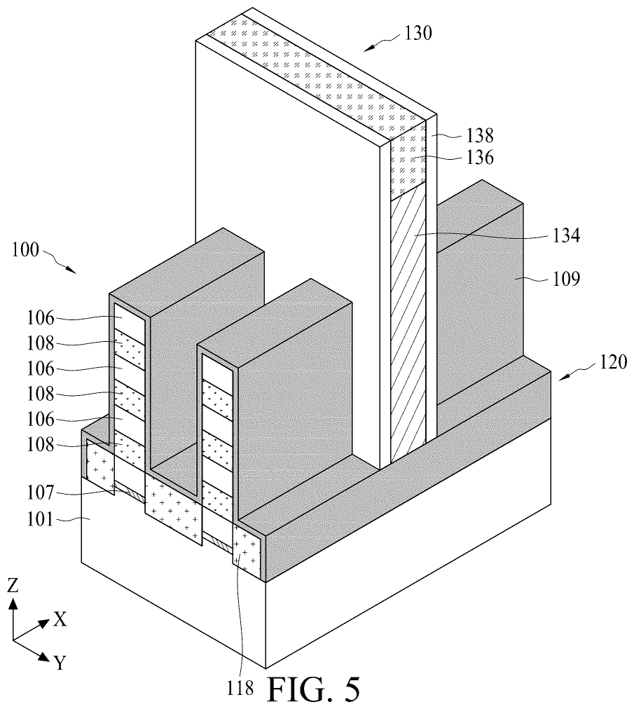

In FIG. 4, the insulating material 118 is recessed to form an isolation region 120. The recess of the insulating material 118 exposes portions of the fin structures 112, such as the stack of semiconductor layers 104. The recess of the insulating material 118 reveals the trenches 114 between the neighboring fin structures 112. The isolation region 120 may be formed using a suitable process, such as a dry etching process, a wet etching process, or a combination thereof. A top surface of the insulating material 118 may be level with or at a below a surface of the second semiconductor layers 108 in contact with the well portion 116 formed from the substrate 101. Thereafter, an optional liner 109 is formed on the isolation region 120 and exposed surfaces of the fin structures 112. The liner 109 may be made of an oxygen-containing material, a dielectric material, such as SiO₂, SiN, SiCN, SiOC, SiOCN, or the like, or any suitable material that has high etch selectivity with respect to the first and second semiconductor layers 106, 108. The liner 109 protects the first and second semiconductor layers 106, 108 from being damaged during the subsequent removal of the sacrificial gate structure. The liner 109 may also serve as a sacrificial gate dielectric layer for the subsequent sacrificial gate structures 130 (FIG. 5). The liner 109 may be a conformal layer and may be formed by a conformal process, such as an atomic layer deposition (ALD) process.

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate electrode layer 134 and a mask layer 136. The sacrificial gate electrode layer 134 and the mask layer 136 may be formed by sequentially depositing blanket layers of the sacrificial gate electrode layer 134 and the mask layer 136, and then patterning these layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. While one sacrificial gate structure 130 is shown, it should be understood that two or more sacrificial gate structures 130 may be arranged along the X direction, such as the embodiments shown in FIGS. 12A-12B to 42A-42B.

The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 serve as channel regions for the semiconductor device structure 100. The fin structures 112 that are partially exposed on opposite sides of the sacrificial gate structure 130 define source/drain (S/D) regions for the semiconductor device structure 100. In some cases, some S/D regions may be shared between various transistors. For example, various one of the S/D regions may be connected together and implemented as multiple functional transistors.

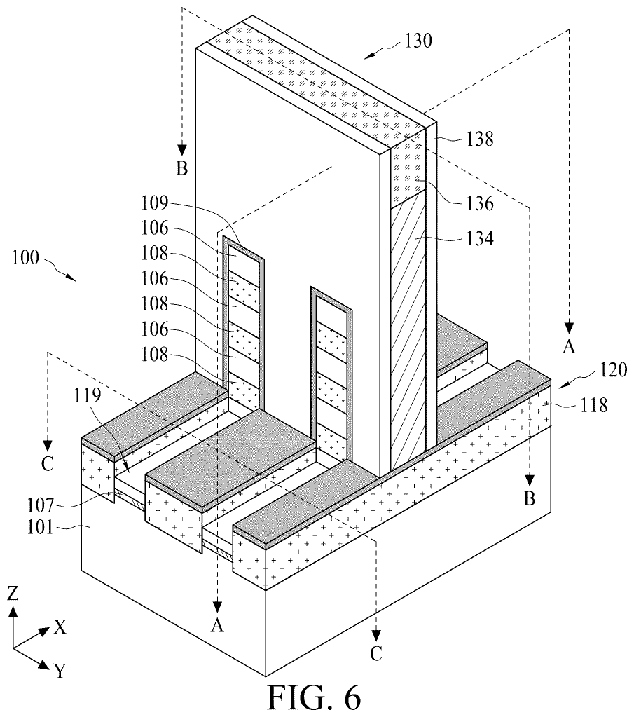

In FIG. 6, the portions of the fin structures 112 in the S/D regions (e.g., regions on opposite sides of the sacrificial gate structure 130) are recessed down below the top surface of the isolation region 120 (or the insulating material 118), by removing portions of the fin structures 112 not covered by the sacrificial gate structure 130. The removal process may not etch the sacrificial layer 107. The recess of the portions of the fin structures 112 can be done by any suitable etch process. Trenches 119 are formed in the S/D regions as the result of the recess of the portions of the fin structures 112.

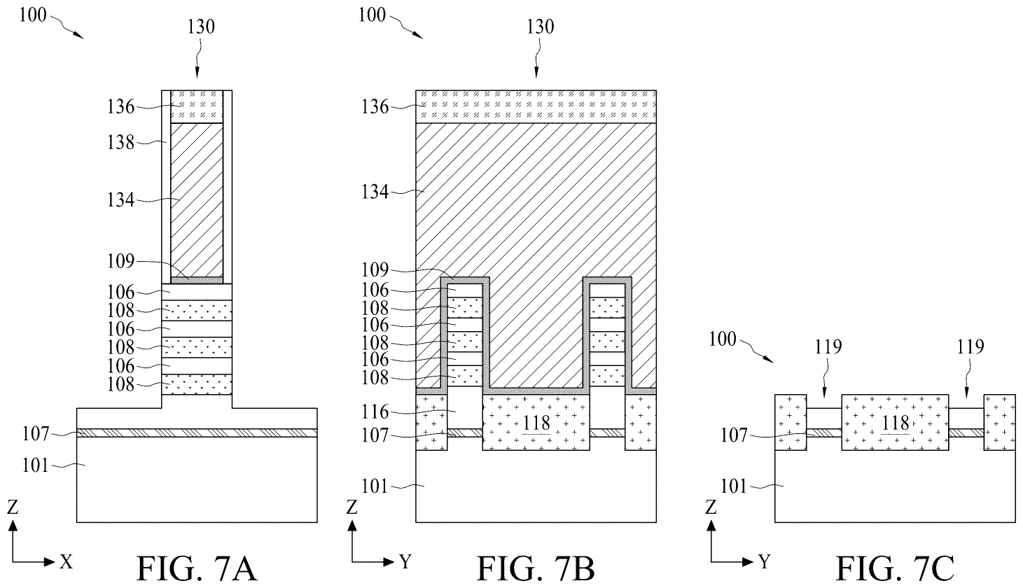

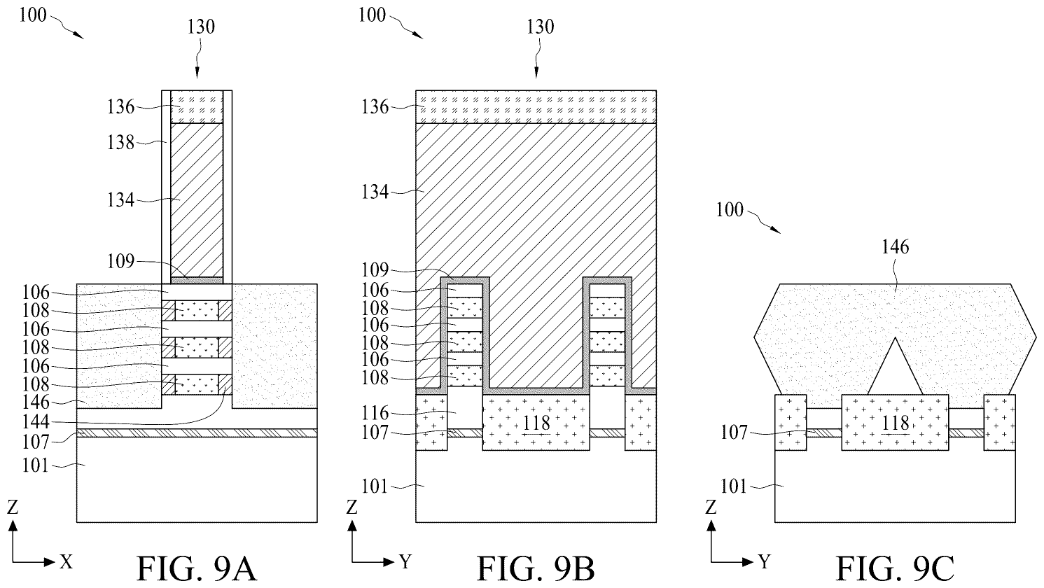

FIGS. 7A-11A are cross-sectional side views of various stages of manufacturing the semiconductor device structure 100 taken along cross-section A-A of FIG. 6, in accordance with some embodiments. FIGS. 7B-11B are cross-sectional side views of various stages of manufacturing the semiconductor device structure 100 taken along cross-section B-B of FIG. 6, in accordance with some embodiments. FIGS. 7C-11C are cross-sectional side views of various stages of manufacturing the semiconductor device structure 100 taken along cross-section C-C of FIG. 6, in accordance with some embodiments. Cross-section A-A are in a plane of the fin structure 112 (FIG. 4) along the X direction. Cross-section B-B is in a plane perpendicular to cross-section A-A and is in the sacrificial gate structure 130 along the Y direction. Cross-section C-C is in a plane perpendicular to cross-section A-A and is in the epitaxial S/D features 146 (FIG. 9A) along the Y-direction.

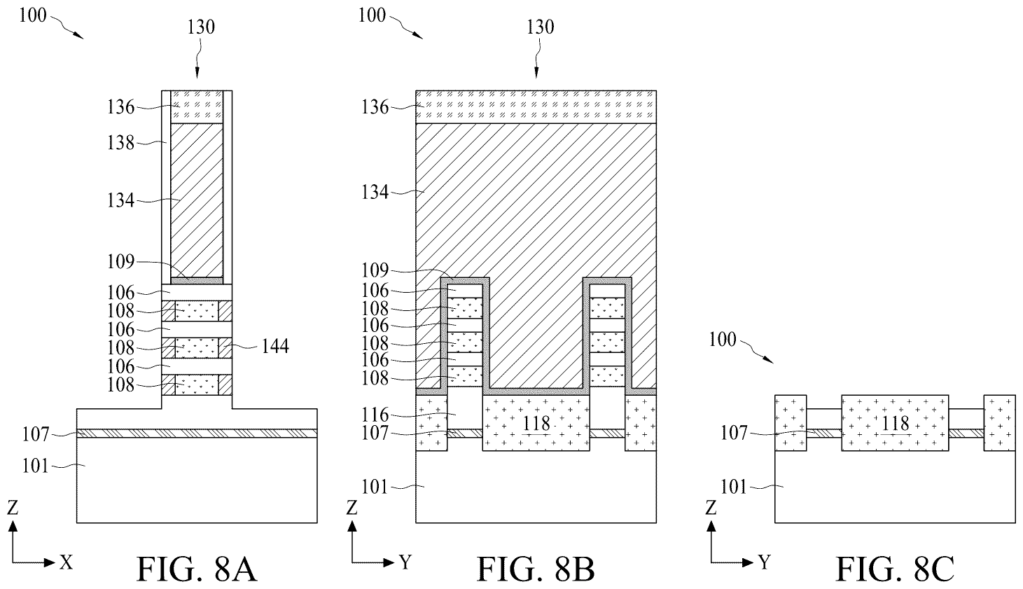

In FIGS. 8A-8C, edge portions of each second semiconductor layer 108 of the stack of semiconductor layers 104 are removed horizontally along the X direction. The removal of the edge portions of the second semiconductor layers 108 forms cavities. Next, a dielectric layer is formed on exposed surfaces of the sacrificial gate structures 130 and the first and second semiconductor layers 106, 108. The dielectric layer fills in the cavities provided by removal of the edge portions of the second semiconductor layers 108. Suitable materials for the dielectric layer may include, but are not limited to, SiO₂, Si₃N₄, SiC, SiCP, SiON, SiOC, SiCN, SiOCN, and/or other suitable material. The dielectric layer may be formed by a conformal deposition process, such as ALD. Then, a removal process, such as an anisotropic etching process, is performed so that only portions of the dielectric layer 144 remain in the cavities to form inner spacers 144. The remaining second semiconductor layers 108 are capped between the inner spacers 144 along the X direction.

In FIGS. 9A-9C, epitaxial S/D features 146 are formed in the source/drain (S/D) regions. The epitaxial S/D features 146 may grow vertically and horizontally to form facets, which may correspond to crystalline planes of the material used for the first semiconductor layers 106. In some cases, the epitaxial S/D features 146 of a fin structure may grow and merge with the epitaxial S/D features 146 of the neighboring fin structures, as one example shown in FIG. 9C. In some embodiments, the epitaxial S/D features 146 of a fin structure may not merge with the epitaxial S/D features 146 of the neighboring fin structures. The epitaxial S/D feature 146 may include one or more layers of Si, SiP, SiC and SiCP for an n-type FET or Si, SiGe, Ge for a p-type FET. The epitaxial S/D features 146 may be formed by an epitaxial growth method using selective epitaxial growth (SEG), CVD, ALD or MBE. The epitaxial S/D features 146 are in contact with the first semiconductor layers 106 and the inner spacers 144. The second semiconductor layers 108 under the sacrificial gate structure 130 are separated from the epitaxial S/D features 146 by the dielectric spacers 144.

The epitaxial S/D features 146 may be the S/D regions. For example, one of a pair of epitaxial S/D features 146 located on one side of the sacrificial gate structures 130 may be a source region, and the other of the pair of epitaxial S/D features 146 located on the other side of the sacrificial gate structures 130 may be a drain region. A pair of S/D epitaxial features 146 includes a source epitaxial feature 146 and a drain epitaxial feature 146 connected by the channels (i.e., the first semiconductor layers 106). Source/drain region(s) may refer to a source or a drain, individually or collectively dependent upon the context. In this disclosure, a source and a drain are interchangeably used, and the structures thereof are substantially the same.

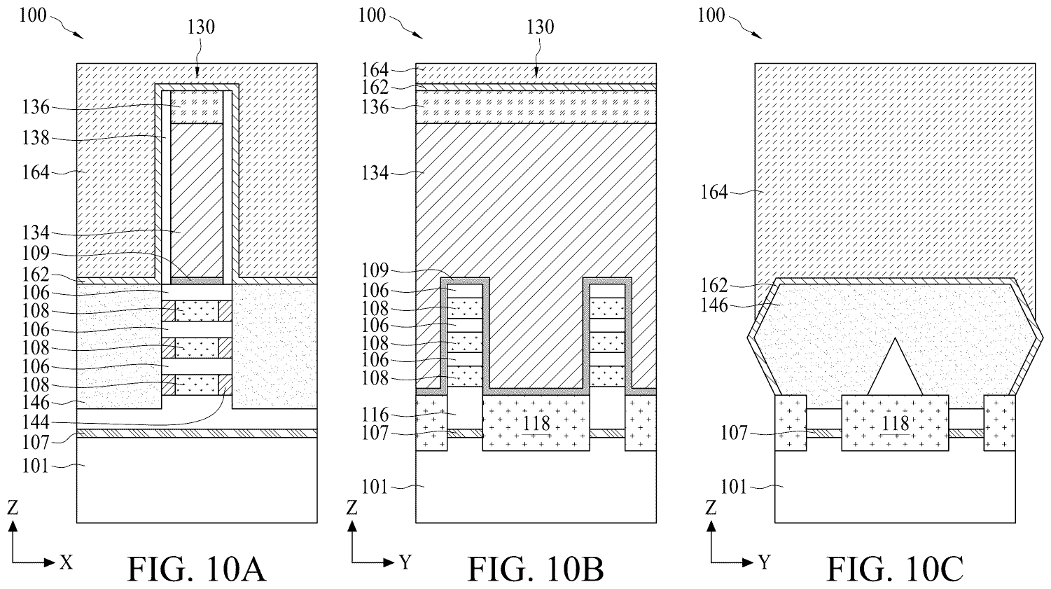

In FIGS. 10A-10C, a contact etch stop layer (CESL) 162 is conformally formed on the exposed surfaces of the sacrificial gate structure 130, the insulating material 118, the epitaxial S/D features 146, and the exposed surface of the stack of semiconductor layers 104. The CESL 162 may include an oxygen-containing material or a nitrogen-containing material, and may be formed by CVD, PECVD, ALD, or any suitable deposition technique. Next, a first interlayer dielectric (ILD) layer 164 is formed on the CESL 162 over the semiconductor device structure 100. The materials for the first ILD layer 164 may include compounds comprising Si, O, C, and/or H, such as silicon oxide, TEOS oxide, SiCOH and SiOC. Organic materials, such as polymers, may also be used for the first ILD layer 164.

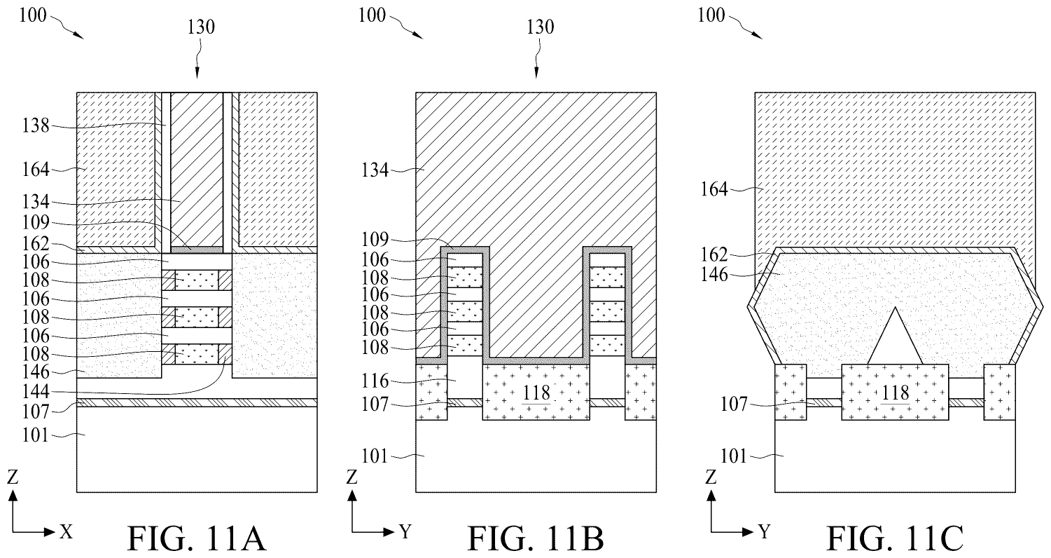

In FIGS. 11A-11C, after the first ILD layer 164 is formed, a planarization operation, such as CMP, is performed on the semiconductor device structure 100 until the sacrificial gate electrode layer 134 is exposed. The top surfaces of the sacrificial gate electrode layer 134, the gate spacers 138, the CESL 162, and the first ILD layer 164 are substantially co-planar after the CMP.

FIGS. 12A-12B to 21A-21B and 23A-23B to 40A-40B are cross-sectional side views of one of various stages of manufacturing the semiconductor device structure 100 of FIGS. 11A and 11B showing multiple fin structures disposed along the X and Y directions, respectively, in accordance with some embodiments. FIGS. 12A and 12B show an embodiment where the first ILD layer 164 is recessed to a level below the top of the sacrificial gate electrode layer 134 prior to the CMP process. In such cases, a cap layer 139, such as a SiN, SiCN, or TiN layer, may be formed on the recessed first ILD layer 164. The cap layer 139 may protect the first ILD layer 164 during subsequent CMP and etch processes. After the planarization process, the top surfaces of the cap layer 139, the CESL 162, the gate spacers 138, and the sacrificial gate electrode layer 134 are substantially co-planar. Although three fin structures are illustrated in the Y-cut figures, it is understood that depending on the desired design and number of the GAA semiconductor device structure 100, any suitable number of fin structures may be formed in the multi-layer structure to form the desired GAA semiconductor device structures 100.

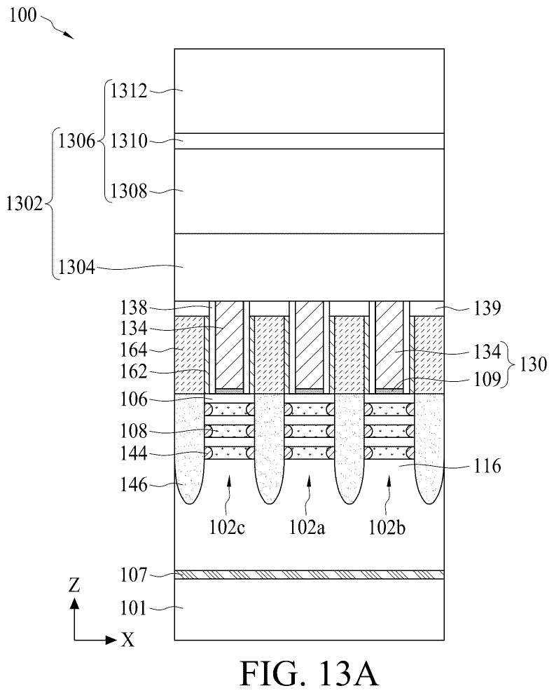

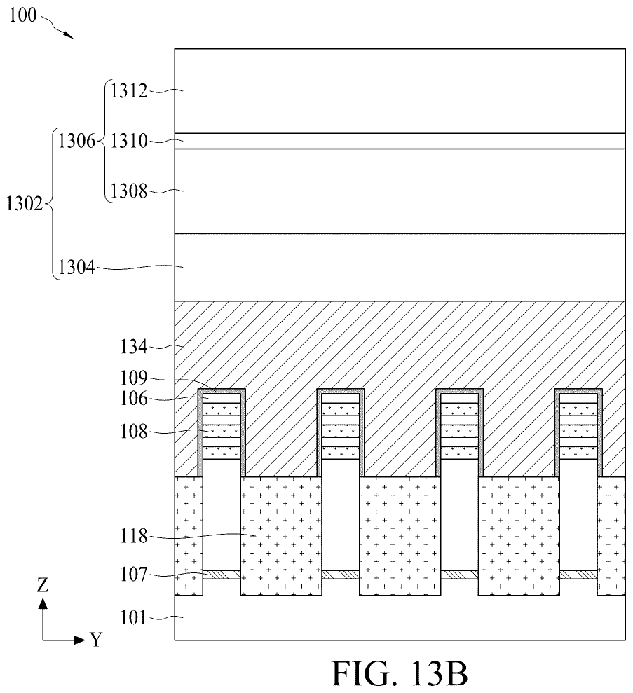

In FIGS. 13A and 13B, a mask structure 1302 is formed on the top surfaces of the sacrificial gate electrode layer 134, the gate spacers 138, the CESL 162, and the cap layer 139 (or the first ILD layer 164 if the cap layer 139 were not formed). The mask structure 1302 may include a hard mask 1304 and a resist layer 1306. The hard mask 1304 may be any suitable masking material. In some embodiments, the hard mask 1304 is formed of a nitrogen-containing material, such as a SiN or SiCN. The resist layer 1306 may be a single layer photoresist or a tri-layer photoresist. An exemplary tri-layer photoresist may include a bottom layer 1308, a middle layer 1310 disposed over the bottom layer 1308, and a photoresist top layer 1312 disposed over the middle layer 1310. The resist layer 1306 may be formed by any suitable process, such as a spin-on coating. The bottom layer 1308 may be a bottom anti-reflective coating (BARC) layer. The middle layer 1310 may be a silicon-containing inorganic polymer that provides anti-reflective properties and/or hard mask properties for a photolithography process. The photoresist top layer 1312 may be a DUV resist (KrF) resist, an argon fluoride (ArF) resist, an EUV resist, an electron beam (e-beam) resist, or an ion beam resist.

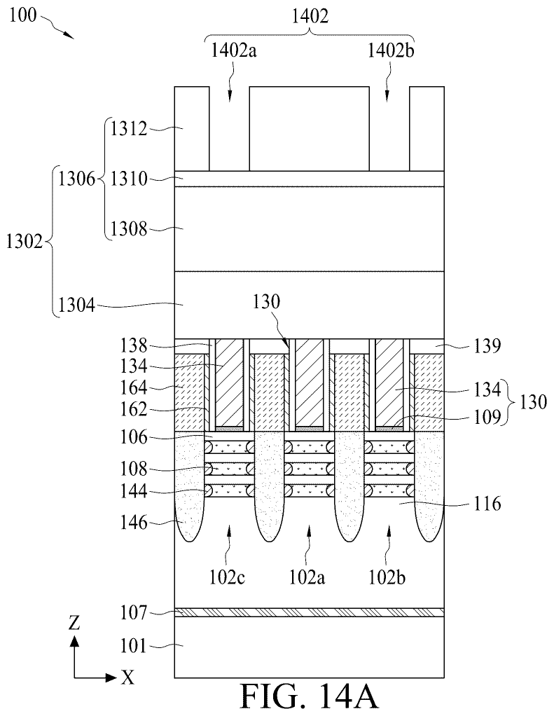

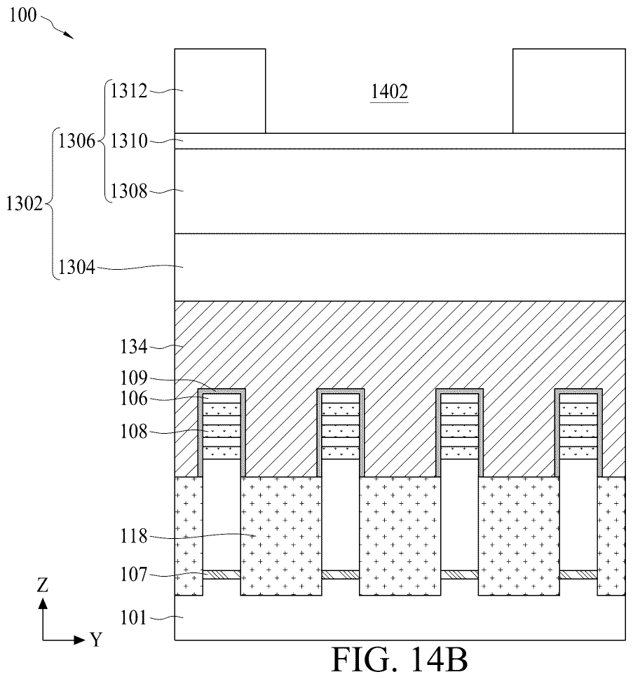

In FIGS. 14A and 14B, the photoresist top layer 1312 is patterned to form a plurality of photoresist mandrels separated from each other by an opening. For case of illustration, only two opening 1402a, 1402b are shown. The patterned photoresist top layer 1312 is used as a mask to transfer the pattern (i.e., openings 1402a, 1402b) in the photoresist top layer 1312 into the middle layer 1310, the bottom layer 1308, and the mask layer 1304. The openings 1402a, 1402b define isolation trenches to be formed in the substrate portions of the fin structures 102b, 102c. The isolation trenches may be disposed between neighboring active regions. The term “active region” refers to a region where transistors are formed. As will be discussed in more detail below, the isolation trenches may be formed by performing a fin-cut (or sheet-cut) process. The isolation trenches are then filled with a dielectric to form continuous poly on diffusion edge (CPODE) trenches. This fin-cut (or sheet-cut) process may be referred to a CPODE process. The term “diffusion edge” is equivalently referred to as an active edge, which is an edge abutting adjacent active regions. The CPODE process can be used to reduce gate pitch, thereby increasing the density for multi-gate devices and thus device performance required for aggressively scaled circuits and devices.

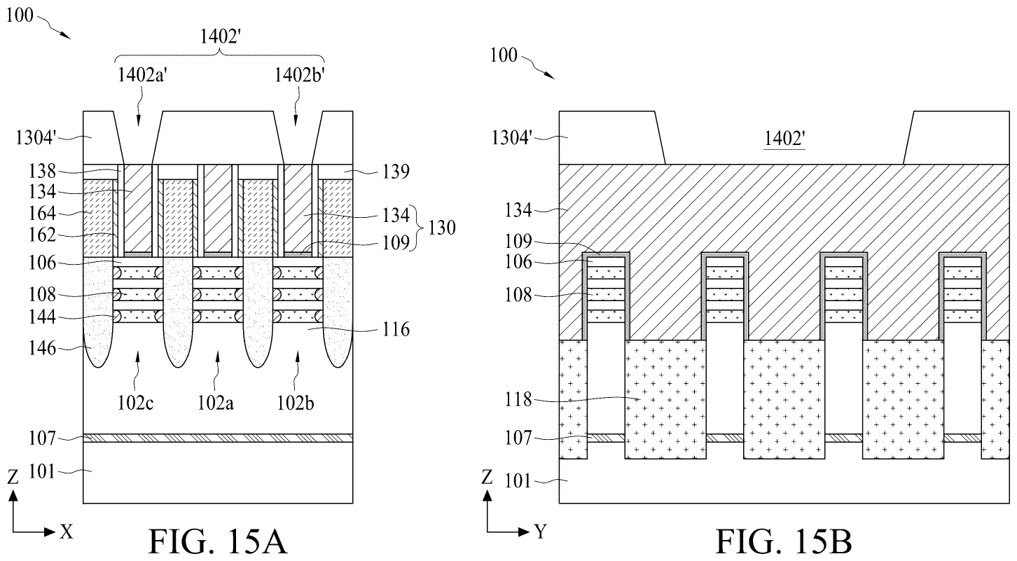

In FIGS. 15A and 15B, the patterns (i.e., openings 1402a, 1402b) in the photoresist top layer 1312 (FIGS. 14A and 14B) are transferred to the mask layer 1304 to form patterned mask layer 1304′. The bottom layer 1308, the middle layer 1310, the photoresist top layer 1312 are then removed. The formation of the patterned mask layer 1304′ may be achieved by one or more photolithographic processes. As a result of the one or more photolithographic processes, portions of the hard mask 1304 are removed, and trench patterns 1402a′, 1402b′ (collectively referred to as trench pattern 1402′) are formed in the patterned mask layer 1304′, and a portion of the sacrificial gate electrode layer 134 is exposed. The trench patterns 1402a′, 1402b′ are elongated openings in alignment with the sacrificial gate structures 130. The removal of portions of the hard mask 1304 (and native oxide formed thereon) may be performed using an etch chemistry, such as CF₄, CHF₃, CH₂F₂, CHF₃, C₄F₆, or the like. The patterned mask layer 1304′ may then be used to protect active regions during subsequent removal of the exposed sacrificial gate structures and fin-cut (or sheet-cut) process.

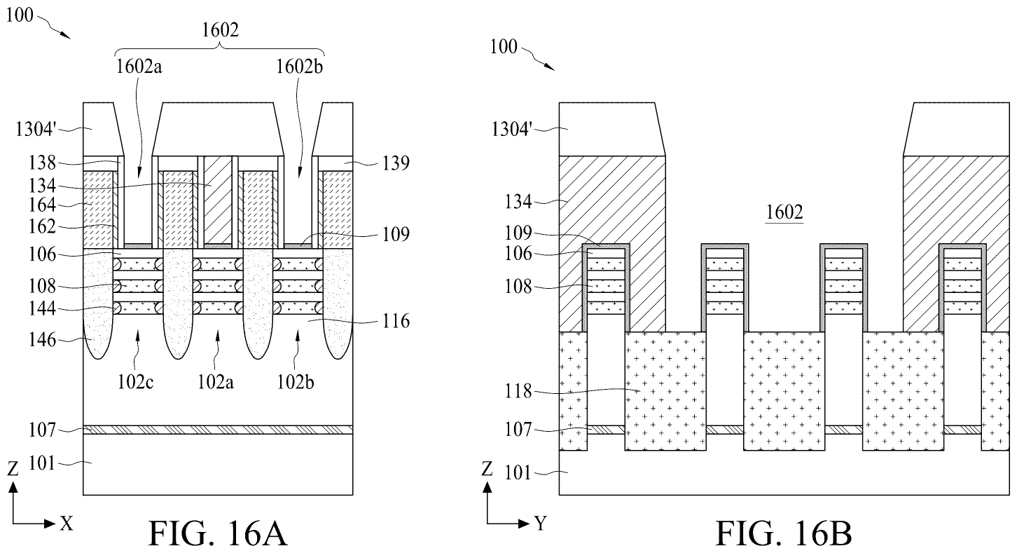

In FIGS. 16A and 16B, the exposed sacrificial gate structures (e.g., sacrificial gate electrode layer 134) are selectively removed to form openings 1602a, 1602b (collectively referred to as openings 1602). The openings 1602 expose the gate spacers 138 and the liner 109. The removal of the exposed sacrificial gate structures may be performed by a selective etch process that removes the sacrificial gate electrode layer 134 but does not substantially affect the gate spacers 138 and the liner 109. The liner 109 protects the first and second semiconductor layers 106, 108 during the etch back process. In some embodiments, the liner 109 may also be removed during the selective etch process. In some embodiments, an etch chemistry that is selective to the sacrificial gate structures to be etched, while minimizing etching of the surrounding dielectric layers, such as the insulating material 118, the gate spacers 138, the CESL 162, and the first ILD layer 164. In some embodiments, the sacrificial gate structures 130 may be removed using chlorine containing gases, such as SiCl₄, BCl₃, Cl₂, CHCl₃, CCl₄, and/or BCl₃, bromine-containing gas, such as HBr and/or CHBr₃, iodine-containing gas, other suitable gases and/or plasmas, and/or combinations thereof.

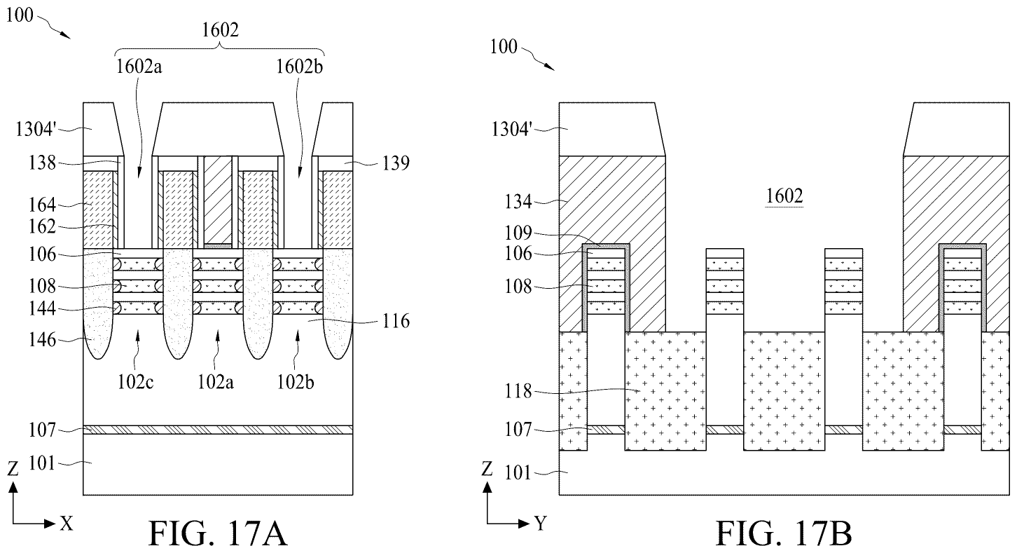

In FIGS. 17A and 17B, an etch process is performed to remove the liner 109. The etch process may be a dry etch, a wet etch, or a combination thereof. The etch process selectively removes the liner 109 without affecting the first and second semiconductor layers 106, 108, as well as the sacrificial gate electrode layer 134.

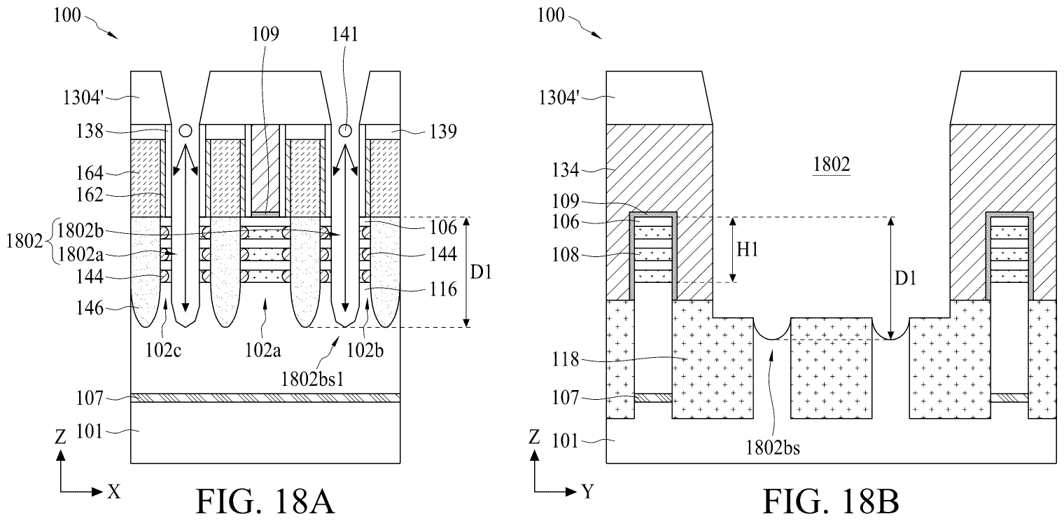

FIGS. 18A and 18B to 21A and 21B illustrate processes of extending the openings 1602 into substrate portions of fin structures 102b, 102c for forming isolation trenches. Particularly, the isolation trenches (and thus subsequent CPODE structures) are formed with a straight and symmetric sidewall profile to facilitate a back side power rail application. In FIGS. 18A and 18B, a first semiconductor etch process 141 is performed to remove the first and second semiconductor layers 106, 108, thereby forming a first section of the isolation trenches 1802. The first semiconductor etch process 141 is a fin-cut (or sheet-cut) process. The first semiconductor etch process 141 is performed using the patterned and shifted mask layer 1304′ as an etching mask. The first semiconductor etch process 141 may be dry etch, reactive ion etch (RIE), and/or other suitable processes. The first semiconductor etch process 141 is performed so that the exposed first semiconductor layers 106, the second semiconductor layers 108, and portions of the substrate 101 forming the fin structures 102b, 102c are selectively removed. A portion of the insulating material 118 around the fin structures 102b, 102c may also be removed. In some embodiments, the removal of the exposed first semiconductor layers 106, the second semiconductor layers 108, and portions of the substrate 101 is achieved using a self-aligned CPODE etch process. The self-aligned CPODE etch process is configured to have high etch selectivity so that the etch rate of the first and second semiconductor layers 106, 108 is greater than the etch rate of the inner spacers 144. As a result, the inner spacers 144 remain substantially intact after the fin-cut process.

As a result of the first semiconductor etch process 141, isolation trenches 1802a, 1802b (collectively referred to as isolation trenches 1802) are formed and extended into portions of the substrate 101 forming the fin structures 102b, 102c (FIG. 17A). In various embodiments, the first semiconductor etch process 141 is performed such that the first section of the isolation trenches 1802a, 1802b are formed with a straight and symmetric sidewall profile with respect to an imaginary line passing through a center of the respective isolation trenches 1802a, 1802b in the depth direction of the isolation trenches 1802a, 1802b. In some embodiments, the isolation trenches 1802a, 1802b may have a first depth D1, which is defined by a distance between the topmost first semiconductor layer 106 and a bottom surface 1802bs1 of the isolation trenches 1802a, 1802b. The first depth D1 may be selected according to desirable level of the narrowest CD. In some embodiments, the bottom surface 1802bs1 of the isolation trenches 1802a, 1802b is at substantially the same elevation as the bottom of the epitaxial S/D features 146. In some embodiments, the bottom surface 1802bs1 of the isolation trenches 1802a, 1802b is below a top surface of the well portion of the substrate 101. In some embodiments, the first depth D1 is in a range between about 30 nm to about 100 nm, which may vary depending on the height of the epitaxial S/D features 146. In some embodiments, the first depth D1 should substantially equal to the height of the epitaxial S/D features. In some embodiments, a ratio of the first depth D1 over a height H1 of the stack of semiconductor layers 104 may be in a range between about 1.1 and about 1.5.

The self-aligned CPODE etch process can be achieved by a plasma etch using a bromine-based etch chemistry and an oxygen-based chemistry. Exemplary bromine-based etch chemistry may include, but are not limited to, HBr, Br₂, BBr₃, or the like, or a combination thereof. Exemplary oxygen-based etch chemistry may include, but are not limited to, O₂, CO₂, O₃, water vapor, or the like, or a combination thereof. In some embodiments, the plasma etch is a high density plasma process chamber using an ICP (inductive coupled plasma) or dipole antenna plasma source. In some embodiments, resonant antenna plasma source or electron cyclotron resonance (ECR) plasma source may also be used to enable low pressure operation (e.g., about 0.2±0.05 mTorr). The plasma may be driven by an RF power generator using an AC electrical current operating on a frequency of multiple of 13.56 MHZ. The process chamber may be operated at a pressure in a range of about 0.2 mTorr to about 150 mTorr and a temperature of about 20 degrees Celsius to about 120 degrees Celsius. The RF power generator is operated to provide source power between about 100 W to about 2500 W. A bias voltage operating in a range of about 0 W to about 2500 W may be applied to a substrate pedestal in the process chamber. In some cases, a pulse plasma etch may be used. In such cases, the output of the power generator may be controlled by a pulse signal having a duty cycle in a range of about 5% to 95%. Alternatively, the self-aligned CPODE etch process may use a bias voltage only (with zero source power) to enhance etch directionality.

While a bromine-based etch chemistry is discussed, other etch chemistry, such as a chlorine-based etch chemistry or a fluorine-based etch chemistry, may also be used. Exemplary chlorine-based etch chemistry may include, but are not limited to, Cl₂, CHCl₃, CCl₄, BCl₃, or the like, or a combination thereof. Exemplary fluorine-containing gas may include, but are not limited to, CF₄, SF₆, CH₂F₂, C₂H₄F₂, CHF₃, C₂F₆, or the like, or a combination thereof. Alternatively, the etchant used in the first semiconductor etch process 141 may be, a chlorine/bromine-based etch chemistry, a fluorine/chlorine-based etch chemistry, a fluorine/bromine-based etch chemistry, or any combination thereof.

In some embodiments, the plasma etch may be performed in a plasma etch chamber with in-situ ALD capability forming silicon oxide or silicon nitride so that a passivation layer with sufficient protection may be formed in a subsequent operation.

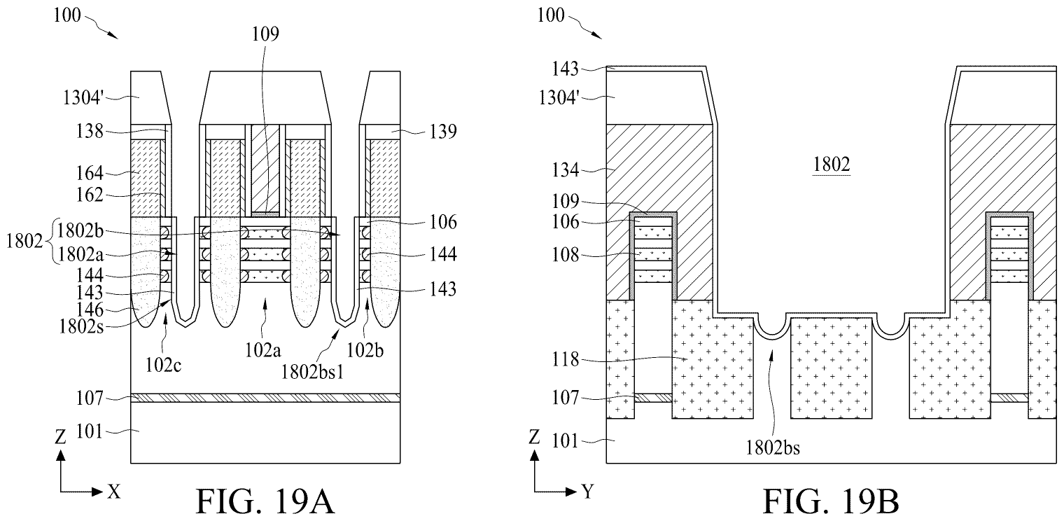

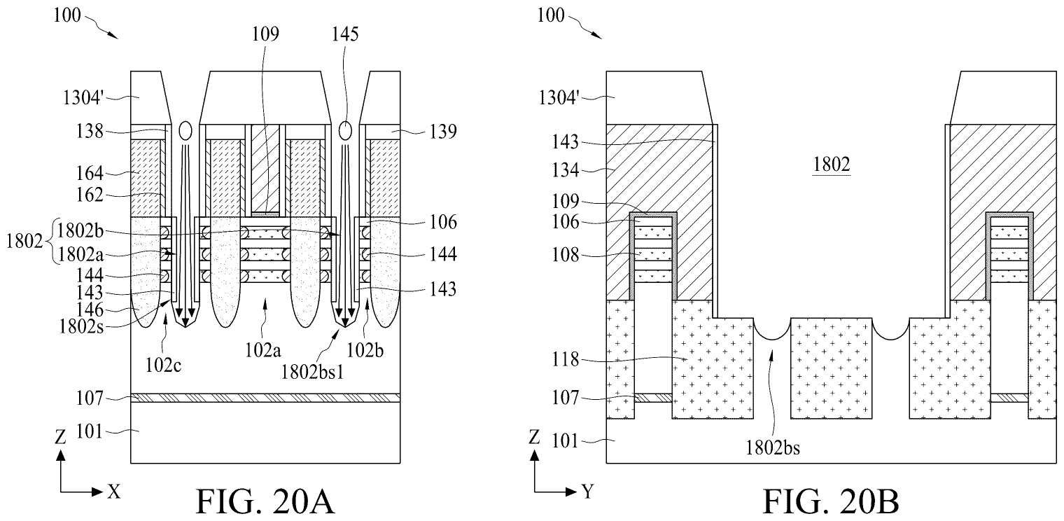

In FIGS. 19A and 19B, a passivation layer 143 is formed over the exposed surfaces of the isolation trenches 1802a, 1802b, such as a sidewall 1802s and a bottom surface 1802bs1 of the isolation trenches 1802. The passivation layer 143 is configured to lower the etching selectivity of the exposed surfaces of the isolation trenches 1802a, 1802b to the etchants used for subsequent etch process, such as a break-through etch process shown in FIGS. 20A and 20B. Therefore, while the etchants may still remove a portion of the passivation layer 143, the passivation layer 143 at the bottom surface 1802bs1 of the isolation trenches 1802 and the underlying silicon substrate are removed at a faster rate than the rate of the passivation layer 143 (with the aid of a bias voltage to the substrate support) on the sidewall 1802s of the isolation trenches 1802.

Unlike the traditional approach which modifies the selectivity of etching recipes (e.g., use high selective etching recipe) in accordance with the materials to be etched for forming isolation trenches, the passivation layer 143 is configured to lower the etching selectivity of the exposed surfaces of the isolation trenches 1802a, 1802b to the etchants used for subsequent etch process, such as a break-through etch process shown in FIGS. 20A and 20B. Therefore, while the etchants may still remove a portion of the passivation layer 143, the passivation layer 143 at the bottom surface 1802bs1 of the isolation trenches 1802 and the underlying silicon substrate are removed at a faster rate than the rate of the passivation layer 143 (with the aid of a bias voltage to the substrate support) on the sidewall 1802s of the isolation trenches 1802. With this approach, the impact of the etchant (e.g., a break-through etch process 145 discussed below with respect to FIGS. 20A and 20B) on the sidewall of the isolation trenches is minimized by the passivation layer, making it a low-selectivity etching process. Therefore, the isolation trenches 1802a, 1802b can be extended vertically with a straight and symmetric sidewall profile without a bowing phenomenon, which may otherwise occur if a high selective etching recipe was used to remove the passivation layer or a too-thick passivation layer (e.g., about 6 nm or greater), and therefore excessive etching impact on the lower part of the isolation trenches 1802a, 1802b and/or the substrate 101 adjacent the bottom of the isolation trenches 1802a, 1802b. When the isolation trenches have a bowing profile, the adjacent epitaxial source/drain features 146 may be damaged, the subsequent backside contact may touch the end of the isolation trenches which in turn increases the resistance of the backside contact for source/drain features. In addition, the risk for blocking the subsequent backside contact etch is increased.

The passivation layer 143 may be a dielectric material or an oxide-based passivation layer, such as SiO, SiO₂, SiON, SiN, or SixNy in amorphous phase (ratio of y/x may range between 1 and 2), or the like, or any combination thereof. In some embodiments, the passivation layer 143 is formed with a porous film property (e.g., amorphous). In some embodiments, the passivation layer 143 may be formed by exposing the exposed surfaces of the isolation trenches 1802a, 1802b to plasma with a gas mixture comprising a silicon-containing precursor (e.g., SiCl₄) and an oxygen-containing precursor (e.g., O₂). The precursors of the silicon-containing precursor and the oxygen-containing precursor may flow concurrently or sequentially into the process chamber. In some embodiments, a hydrogen halide such as hydrogen bromide (HBr) may be flowed along with the silicon-containing precursor and the oxygen-containing precursor. In some embodiments, the passivation layer 143 may contain impurities from the precursors, such as Br and/or H. In various embodiments, the passivation layer 143 may have impurities at an atomic percentage of about 30 at. % to about 70 at. %, such as about 45 at. % to about 60 at. %. In one embodiment, the passivation layer 143 is a bromine-containing silicon monoxide (SiO) or SiO₂. In such cases, a gas mixture comprising SiCl₄, HBr, O₂ may be used. Additionally or alternatively, the gas mixture may contain SiCl₄, HBr, SiO (sulfur dioxide) and CO₂ precursors. In another embodiment, the passivation layer 143 is a hydrogen-containing SiO or SiON.

In some embodiments, the passivation layer 143 is deposited by an in-situ ALD process in the same chamber as the plasma etch process used for the first semiconductor etch process 141. For example, an in-site ALD technique uses precursors such as DIPAS (di(isopropylamino)silane) and BTBAS (bis(tertiary-butylamino)silane) in combination with Ar or O₂ plasma treatment to form a silicon-containing film. For example, the passivation layer 143 may be formed by supplying a silicon-containing source gas, such as DIPAS or BTBAS, to the process chamber, supplying a plasma of a reactive gas, such as an oxygen-containing gas or a nitrogen-containing gas, to the process chamber. The radicals from the plasma of the reactive gas oxidize or nitride substances derived from the silicon-containing source gas to form the silicon-containing film.

The etching resistivity of the passivation layer 143 may be controlled by adjusting the thickness, film density, plasma power, temperature, pressure, or composition of the precursors, or any combination thereof. In some embodiments, a lower etching resistivity of passivation layer 143 is achieved by decreasing the deposition time or plasma power, or increasing temperature, and therefore, a thinner passivation layer. In some embodiments, the passivation layer 143 may have a thickness between about 0.5 nm and about 5 nm. In some embodiments, the passivation layer 143 may be formed with enhanced plasma dissociation to achieve different film density. In some embodiments, the passivation layer 143 may be a silicon oxide having a density in a range between about 2.648 g/cm³ and about 4.0 g/cm³.

In FIGS. 20A and 20B, a break-through etch process 145 is performed to remove the passivation layer 143 from the bottom surface 1802bs1 of the isolation trenches 1802a, 1802b. The break-through etch process 145 may be directional (anisotropic) so that the passivation layer 143 is removed from the horizontal surfaces of the semiconductor device structure 100. The removal of the passivation layer 143 reveals the bottom surface 1802bs1 of the isolation trenches 1802, or stated differently, exposes a limited region of the substrate portion forming the fin structures 102b, 102c. In some embodiments, the passivation layer 143 may remain on the sidewalls of the sacrificial gate electrode layer 134 and a portion of the insulating material 118. Since the passivation layer 143 remaining on the sidewall 1802s of the isolation trenches 1802 blocks the etchants from expanding the isolation trenches 1802 laterally, the etchants in the subsequent second semiconductor etch process 147 are restricted to the limited region of the substrate portion forming the fin structures 102b, 102c. As a result, the isolation trenches 1802 are formed with a straight and symmetric sidewall profile along the depth direction of the isolation trenches 1802.

The break-through etch process 145 may use C—H and/or C—F based chemistries, such as CF₄, CHF₃, CH₂F₂, C₄F₆, or the like, or any combination thereof. In some embodiments, in cases where the passivation layer 143 includes bromine-containing SiO, low selective etchants, such as CF₄, C₄F₆, CHF₃, may be used in a high directional break-through etch process to remove the passivation layer 143 from the bottom surface 1802bs1 of the isolation trenches 1802a, 1802b. A bias voltage may be supplied (to a pedestal upon which the semiconductor device structure 100 is disposed) during the break-through etch process 145 to enable anisotropic etching. The use of the bias voltage also compensates for the etch selectivity needed for removing the insulating material 118 and the substrate portion of the fin structures 102b, 102c. Higher directionality can be achieved by adding the bias voltage to the substrate pedestal in the process chamber, and/or lower frequency for bias power. In some embodiments, the bias voltage used during the break-through etch process 145 is greater than that of the first semiconductor etch process 141, and the bias power frequency used during the break-through etch process 145 is lower than that of the first semiconductor etch process 141.

Exemplary break-through etch process 145 for removing portions of passivation layer 143 may utilize a CCP, ICP, or GDP source driven by an RF power generator or a microwave plasma source using a frequency ranging from about 2 MHz to about 2.45 GHZ, such as about 13.56 MHz. The process chamber may be operated at a pressure in a range of about 0.2 mTorr to about 20 Torr and a temperature of about-80 degrees Celsius to about 240 degrees Celsius. The RF power generator is operated to provide source power between about 100 W to about 1000 W, and the output of the RF power generator is controlled by an optional pulse signal having a duty cycle in a range of about 10% to about 90%. The substrate pedestal on which semiconductor device structure 100 is disposed may be biased with respect to the plasma in a range of about 100 W to about 1000 W.

After the break-through etch process 145, the passivation layer 143 is removed from the bottom surface 1802bs1 of the isolation trenches 1802a, 1802b, while a portion of the passivation layer 143 remains on sidewalls 1802s of the isolation trenches 1802a, 1802b.

In some embodiments, the break-through etch process 145 is performed in the same chamber as the process chamber used for depositing the passivation layer 143 and performing the first semiconductor etch process 141. In some embodiments, the process chamber is an ALD chamber.

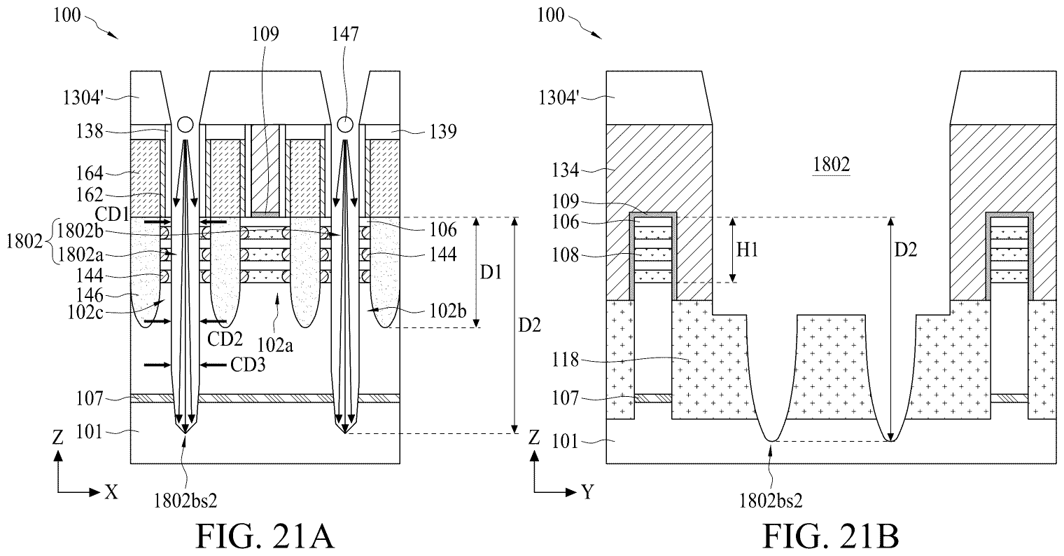

In FIGS. 21A and 21B, a second semiconductor etch process 147 is performed to further remove the substrate portion forming the fin structure 102b, 102c. The second semiconductor etch process 147 also removes the passivation layer 143 remaining on the sidewalls of the isolation trenches 1802a, 1802b. Likewise, the second semiconductor etch process 147 is performed such that a second section of the isolation trenches 1802a, 1802b are formed with a straight and symmetric sidewall profile with respect to an imaginary line passing through a center of the respective isolation trenches 1802a, 1802b in the depth direction of the isolation trenches 1802a, 1802b. In some embodiments, the second section of the isolation trenches 1802a, 1802b are formed in a tapering manner with minimized or no bowing profile. The term “bowing” refers to an aperture within the isolation trenches 1802a, 1802 having a larger diameter than the diameter of the trench pattern 1402a′, 1402b′, which may otherwise occur if ions are asymmetrically scattered in the very narrow etched space of the isolation trenches 1802a, 1802b and/or a too-thick passivation layer was used, as discussed previously. The bowing profile and position may be controlled by tuning the time ratio of passivation, semiconductor etch, and break-through steps. Less passivation but more break-through and semiconductor etch amount can lead to less bowing profiles but wider etch trenches, resulting in higher risk for source or drain damage. As will be discussed in more detail below (e.g., FIGS. 18A-22G), the advantageous etch profile for CPODE/CMODE trenches for backside power rail application should have a triangle, square, or trapezoid shape, which can minimize the risk for blocking the backside contact etch. Isolation trenches 1802a, 1802b having a straight and symmetric sidewall profile are beneficial as they are less likely to interfere with backside contact via for epitaxial source/drain features 146 (e.g., source feature), thereby facilitating back side power rail application.

The second semiconductor etch process 147 may be performed using an etch chemistry similar to the first semiconductor etch process 141. The second semiconductor etch process 147 can be achieved through plasma etch comprising HBr, sometimes with addition of BCl₃. In some cases, BCl₃ may be used to tune the selectivity of Si over silicon oxide, which can be the main composition of passivation layers. In some embodiments, the non-bowing etch profile can be achieved by carefully controlling the ratio of HBr and BCl₃. In some embodiments, the non-bowing profile can also be achieved utilizing etch conditions with low pressure, such as below about 50 mTorr. In some embodiments, O₂ and/or CO₂ may be added to HBr based plasma to facilitate dissociation of the plasma by product. In some embodiments, the plasma etch process may be high density plasma process in condition similar to the first semiconductor etch process 141. In some embodiments, the second semiconductor etch process 147 is performed to extend the isolation trenches 1802a, 1802b into the substrate portion of the fin structures 102b, 102c to a depth below the sacrificial layer 107. The extended isolation trenches 1802a, 1802b have a second depth D2 measuring from the topmost first semiconductor layer 106 to a bottom surface 1802bs2 of the isolation trenches 1802a, 1802b. In other words, the depth of each isolation trench 1802a, 1802b is extended from the first depth D1 to the second depth D2. In some embodiments, the bottom surface 1802bs2 of the isolation trenches 1802a, 1802b may be at an elevation into an accumulation region of the substrate 101. The term “accumulation region” refers to a non-conductive region in the substrate 101, which is below a depletion region (a conductive region located at/near the well portion of the substrate 101). In any case, the second depth D2 is sufficient to block the path of leakage current through epitaxial source/drain features and the silicon substrate. In some embodiments, the second depth D2 may be in a range between about 60 nm and about 200 nm. In some embodiments, a ratio of the second depth D2 over the height H1 of the stack of semiconductor layers 104 may be in a range between about 1.2 and about 4.0.

As shown in FIG. 21A, the isolation trenches 1802a, 1802b have a substantially uniform critical dimension (CD) from top to bottom. In some embodiments, the first section of the isolation trenches 1802a, 1802b at or near the topmost first semiconductor layer 106 has a first CD (CD1), the middle portion of the isolation trenches 1802a, 1802b at or near the bottom of the epitaxial source/drain features 146 has a second CD (CD2), and the second section of the isolation trenches 1802a, 1802b at or near the bottom of the isolation trenches 1802a, 1802b has a third CD (CD3). In some embodiments, the CD1, the CD2, and the CD3 are substantially the same. In some embodiments, the CD1, the CD2, and the CD3 are slightly different from each other. For example, the CD1 may be slightly greater than the CD3, and the CD3 may be slightly greater the CD2. The CD1, the CD2, and the CD3 discussed herein are applicable to both thin-wafer and thick-wafer approaches. In some embodiments, the bottom portion of the isolation trenches 1802a, 1802b below the sacrificial layer 107 may have a tapering shape.

The isolation trenches 1802 with homogeneous CD along the depth direction can be obtained by multi-cycle operations. In some alternative embodiments, the processes in FIGS. 18A and 18B to 21A and 21B may repeat two or more cycles so that the isolation trenches 1802a, 1802b are formed with a uniform CD along the depth direction. That is, the CD1, the CD2, and the CD3 within the isolation trenches 1802a, 1802b, from top to bottom, are substantially the same. The processes in FIGS. 18A and 18B to 21A and 21B may repeat until the isolation trenches 1802 reach a predetermined depth.

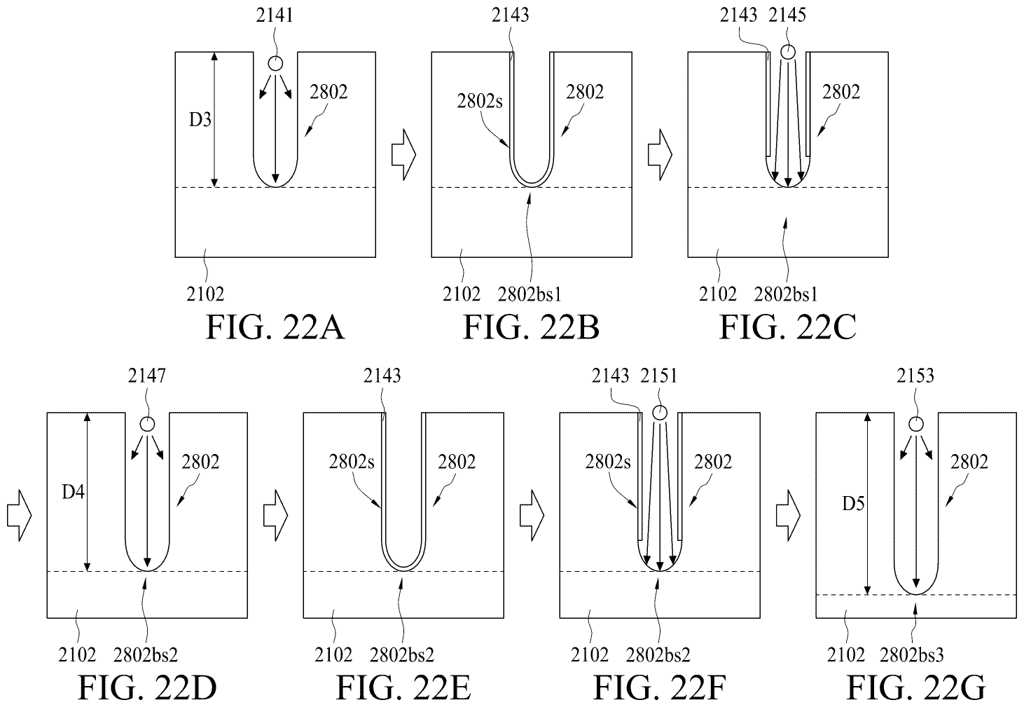

FIGS. 22A-22G illustrate an exemplary cyclic etch process for forming an isolation trench 2802 in accordance with some embodiments. For the sake of simplicity, only a fragmentary portion of the semiconductor device structure 100 is illustrated in FIGS. 22A-22G. In FIG. 22A, a first etch process 2141, such as the first semiconductor etch process 141, is performed to form an isolation trench 2802 (e.g., isolation trench 1802) into a substrate portion 2102 of a fin structure (e.g., fin structure 102b). The isolation trench 2802 may have a first depth D3 measuring from a top of the isolation trench 2802 to a bottom of the isolation trench 2802. In FIG. 22B, a first passivation layer 2143, such as the passivation layer 143, is formed on sidewalls 2802s and bottom surface 2802bs1 of the isolation trench 2802. In FIG. 22C, a first break-through etch process 2145, such as the break-through etch process 145, is performed to remove a portion of the first passivation layer 2143 from the bottom surface 2802bs1 of the isolation trench 2802. The removal of the first passivation layer 2143 reveals the bottom surface 2802bs1 of the isolation trench 2802. In FIG. 22D, a second etch process 2147, such as the second semiconductor etch process 147, is performed to remove the remaining first passivation layer 2143 while extending the depth of the isolation trench 2802 from the first depth D3 to a second depth D4. The extended bottom surface 2802bs2 is at an elevation lower than the bottom surface 2802bs1. In FIG. 22E, a second passivation layer 2149, such as the passivation layer 143, is formed on exposed surfaces of the isolation trench 2802. In FIG. 22F, a second break-through etch process 2151, such as the break-through etch process 145, is performed to remove a portion of the second passivation layer 2149 from the extended bottom surface 2802bs2 of the isolation trench 2802. The removal of the second passivation layer 2149 reveals the extended bottom surface 2802bs2 of the isolation trench 2802. In FIG. 22G, a third etch process 2153, such as the first semiconductor etch process 141, is performed to remove the remaining second passivation layer 2149 while extending the depth of the isolation trench 2802 from the second depth D4 to a third depth D5. The extended bottom surface 2802bs3 is at an elevation lower than the bottom surface 2802bs2. A bias voltage may be supplied (to a pedestal upon which the semiconductor device structure 100 is disposed) during the first etch process 2141, first break-through etch process 2145, and the second etch process 2147 to enable anisotropic etching with greater directionality. The processes described in FIGS. 22A-22G may repeat until the isolation trenches 2802 reach a predetermined depth.

In some embodiments, the first etch process 2141/2147 may be performed for a first period of time (T1) and the first break-through etch process 2145/2153 may be performed for a second period of time (T2), and the ratio of T1:T2 may be about 0.7:1 to about 6:1. In most cases, the first break-through time (T2) should be similar or less than the main etch time (e.g., first etch process). The cyclic process may be repeated 2 to 5 cycles, for example.

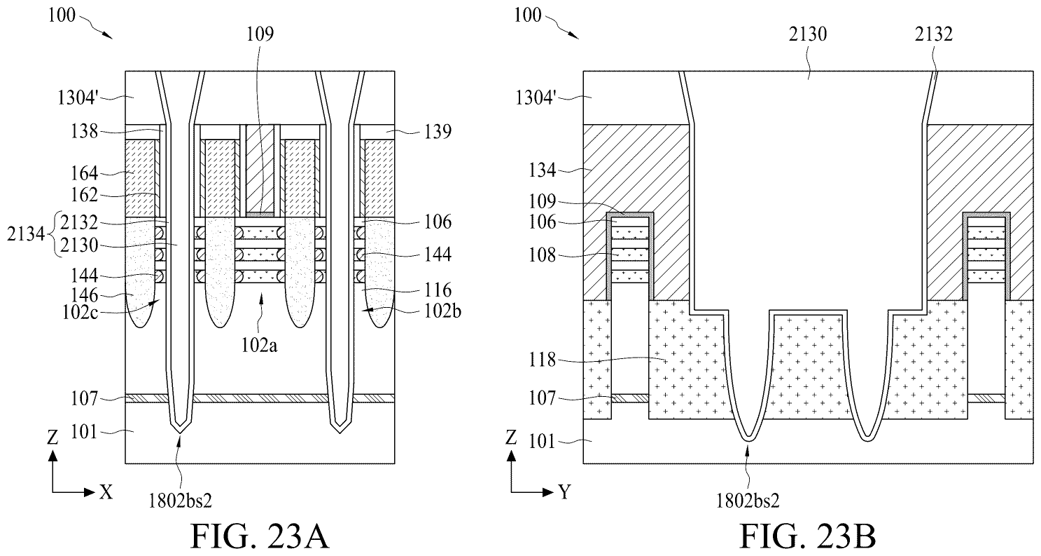

In FIGS. 23A and 23B, the isolation trenches 1802 (FIGS. 21A and 21B) are filled with a dielectric material 2130. In some embodiments, a dielectric liner 2132 may be disposed between the dielectric material 2130 and the exposed surfaces of the isolation trenches 1802. The dielectric material 2130 and the dielectric liner 2132 filled within the isolation trenches 1802 (e.g., isolation trenches 1802a, 1802b shown in FIGS. 21A and 21B) form isolation trench structures (so-called CPODE trenches) 2134. The dielectric material 2130 and the dielectric liner 2132 may be made of an oxygen-containing material, such as silicon oxide (SiO₂); a nitrogen-containing material, such as silicon nitride, silicon oxynitride (SiON), SiOCN, SiCN; a low-K dielectric material; or any suitable dielectric material. The dielectric material 2130 may include a material chemically different than the dielectric liner 2132, and may be formed by any suitable process, such as a CVD, PECVD, FCVD, or ALD process.

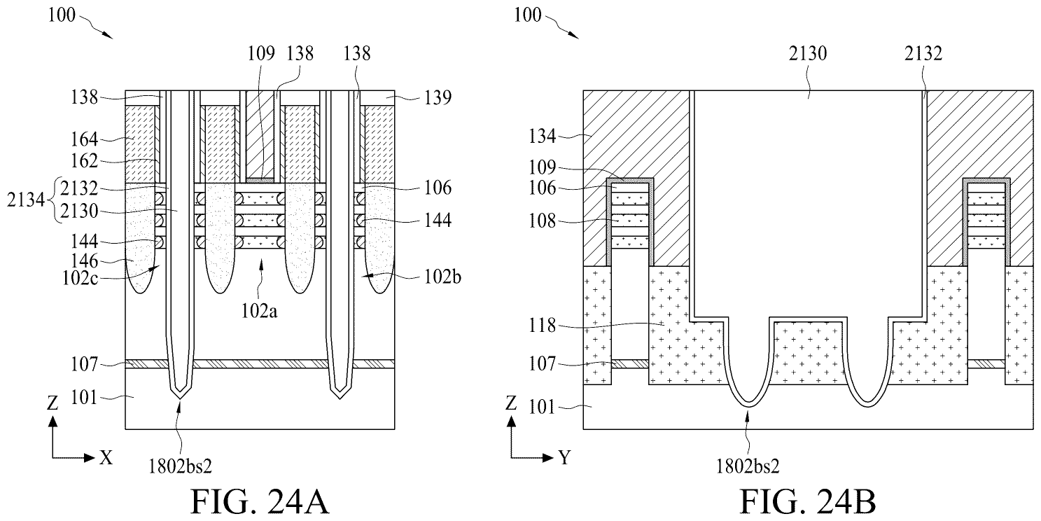

In FIGS. 24A and 24B, once the isolation trenches 1802 are filled, a planarization process, such as a CMP process, may be performed to remove portions of the dielectric material formed over the patterned mask layer 1304′. The planarization process may be performed until a portion of the cap layer 139 or the sacrificial gate electrode layer is exposed.

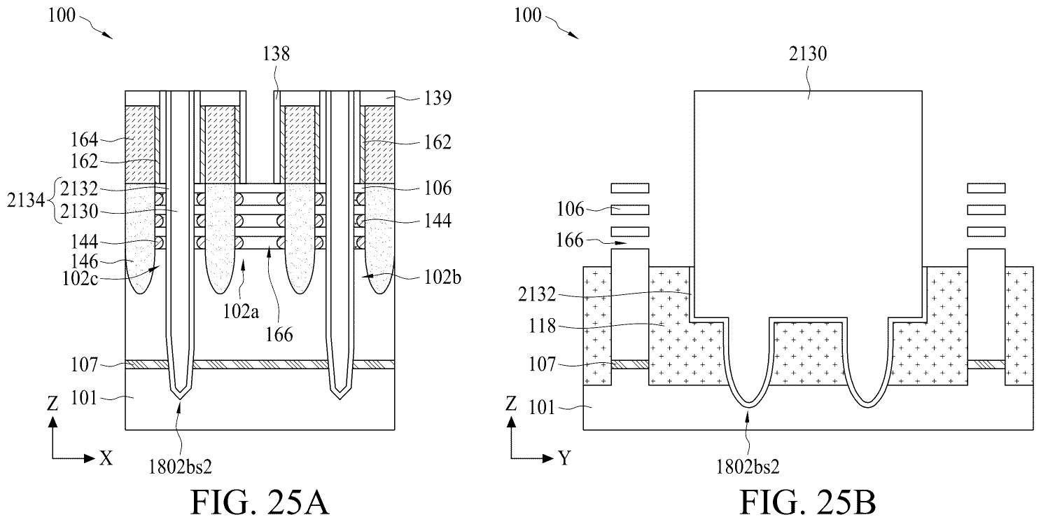

In FIGS. 25A and 25B, the sacrificial gate structures 130, the liner 109, and the second semiconductor layers 108 are removed. The exposed dielectric liner 2132 on the sidewalls of the dielectric material 2130 may also be removed. The removal of the sacrificial gate structures 130 and the semiconductor layers 108 forms an opening 166 between the first semiconductor layers 106. The cap layer 139, the CESL 162, and the first ILD layer 164 protect the epitaxial source/drain features 146 during the removal processes. The sacrificial gate structures 130 can be removed using plasma dry etching and/or wet etching. In some embodiments, a wet etchant such as a tetramethylammonium hydroxide (TMAH) solution can be used to selectively remove the sacrificial gate electrode layer 134 and the liner 109 but not the gate spacers 138, the isolation trench structures 2134, the first ILD layer 164, and the CESL 162. After the removal of the sacrificial gate structures 130, the first semiconductor layers 106 and the inner spacers 144 are exposed to the opening 166.

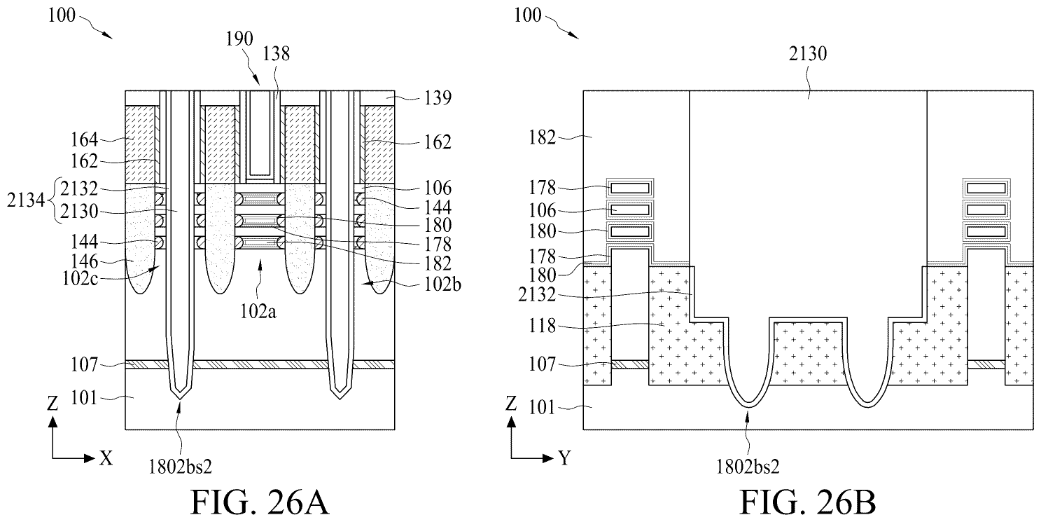

In FIGS. 26A and 26B, replacement gate structures 190 are formed. The replacement gate structures 190 may each include a gate dielectric layer 180 and a gate electrode layer 182. In some embodiments, an interfacial layer (IL) 178 may be formed between the gate dielectric layer 180 and the first semiconductor layer 106. The IL 178 may also form on the exposed surfaces of the substrate 101, the insulating material 118, and the dielectric layer 2132. The IL 178 may include or be made of an oxide (e.g., silicon oxide) formed by thermal or chemical oxidation of the first semiconductor layers 106, a nitride (e.g., silicon nitride, silicon oxynitride, oxynitride, etc.), and/or a dielectric layer (e.g., hafnium silicate). Next, the gate dielectric layer 180 is formed on the exposed surfaces of the semiconductor device structure 100 (e.g., on the IL (if any), sidewalls of the gate spacers 138, the top surfaces of the first ILD layer 164, the CESL 162, and the cap layer 139). The gate dielectric layer 180 may be formed of a material chemically different than that of the sacrificial gate dielectric layer 132. The gate dielectric layer 180 may include or made of a high-k dielectric material. The gate dielectric layer 180 may be a conformal layer formed by a conformal process, such as an ALD process, a PECVD process, a molecular-beam deposition (MBD) process, or the like, or a combination thereof.

After formation of the IL (if any) and the gate dielectric layer 180, the gate electrode layer 182 is formed on the gate dielectric layer 180. The gate electrode layer 182 filles the openings 166 (FIG. 25A) and surrounds a portion of each of the first semiconductor layers 106. The gate electrode layer 182 includes one or more layers of conductive material, such as polysilicon, aluminum, copper, titanium, tantalum, tungsten, cobalt, molybdenum, tantalum nitride, nickel silicide, cobalt silicide, TIN, WN, WCN, TiAl, TiTaN, TiAlN, TaN, TaCN, TaC, TaSiN, metal alloys, other suitable materials, and/or combinations thereof. The gate electrode layers 182 may be formed by PVD, CVD, ALD, electro-plating, or other suitable method. In some embodiments, one or more optional conformal layers (not shown) can be conformally (and sequentially, if more than one) deposited between the gate dielectric layer 180 and the gate electrode layer 182. The one or more optional conformal layers can include one or more barrier and/or capping layers and one or more work-function tuning layers. The one or more barrier and/or capping layers may include or be a nitride, silicon nitride, carbon nitride, and/or aluminum nitride of tantalum and/or titanium; a nitride, carbon nitride, and/or carbide of tungsten; the like; or a combination thereof. The one or more work-function tuning layers may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

Portions of the gate electrode layer 182, the one or more optional conformal layers (if any), and the gate dielectric layer 180 above the top surfaces of the first ILD layer 164, the CESL 162, the cap layer 139 (if any), and the gate spacers 138 may be removed by a planarization process, such as by a CMP process. After the CMP process, the top surfaces of the isolation trench structure 2134, the first ILD layer 164, the CESL 162, the gate spacers 138, and the gate electrode layer 182 are substantially co-planar.

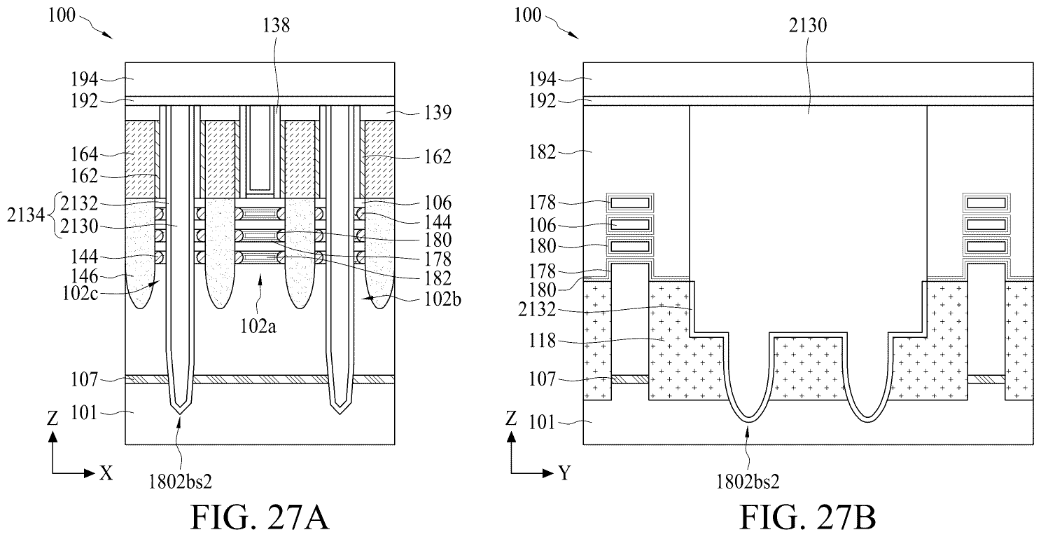

In FIGS. 27A and 27B, a first etch stop layer 192 and a second ILD layer 194 are sequentially formed on the semiconductor device structure 100. The first etch stop layer 192 and the second ILD layer 194 may include the same material as the CESL 162 and the first ILD layer 164, respectively, and may be formed in a similar fashion as discussed above.

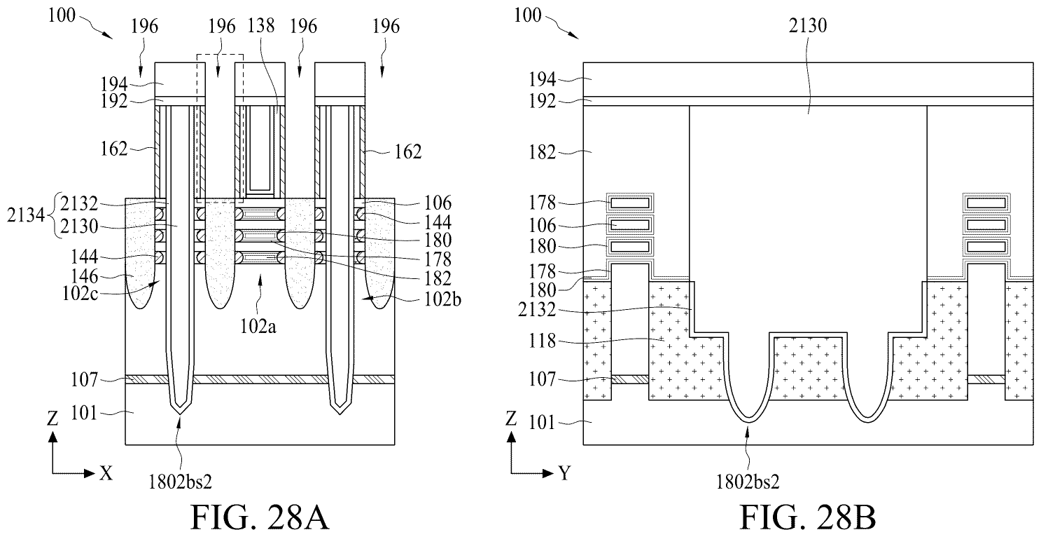

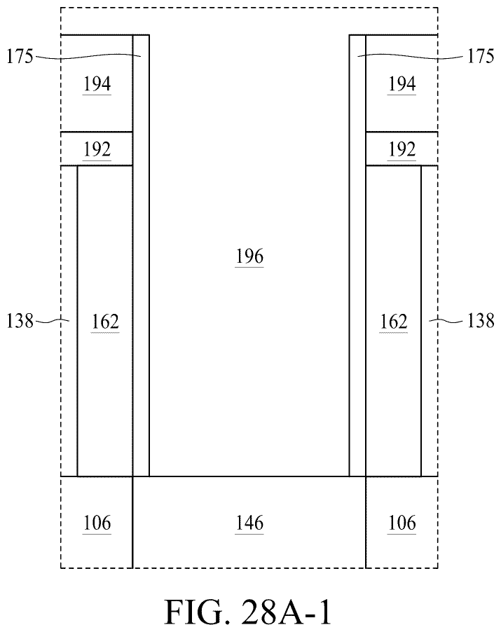

In FIGS. 28A and 28B, one or more etch processes are performed to remove portions of the second ILD layer 194, the first etch stop layer 192, and the first ILD layer 164. In some embodiments, the one or more etch processes may also remove the CESL 162, either partially or in its entirety. As a result of the removal process, openings 196 are formed. Each opening 196 may be an elongated opening and is arranged to align with the corresponding epitaxial S/D feature 146. The openings 196 expose a top surface of the epitaxial S/D features 146. The openings 196 are to be filled with a conductive material and form a metal contact for the epitaxial S/D features 146.

In some embodiments, after the openings 196 are formed, a liner 175 is optionally formed on exposed sidewall surfaces of the first etch stop layer 192, the second ILD layer 194, and the CESL 162. FIG. 28A-1 illustrates an enlarged view of a portion of the semiconductor device structure 100 shown in FIG. 28A, in accordance with some embodiments. The liner 175 may be formed of a dielectric material, such as an oxygen-containing material or a nitrogen-containing material, and may be formed by CVD, PECVD, ALD, or any suitable deposition technique. In some embodiments, the liner 175 includes the same material as the CESL 162. While not shown, it is contemplated that this embodiment can be equally applied to any one or more of the embodiments shown in this disclosure.

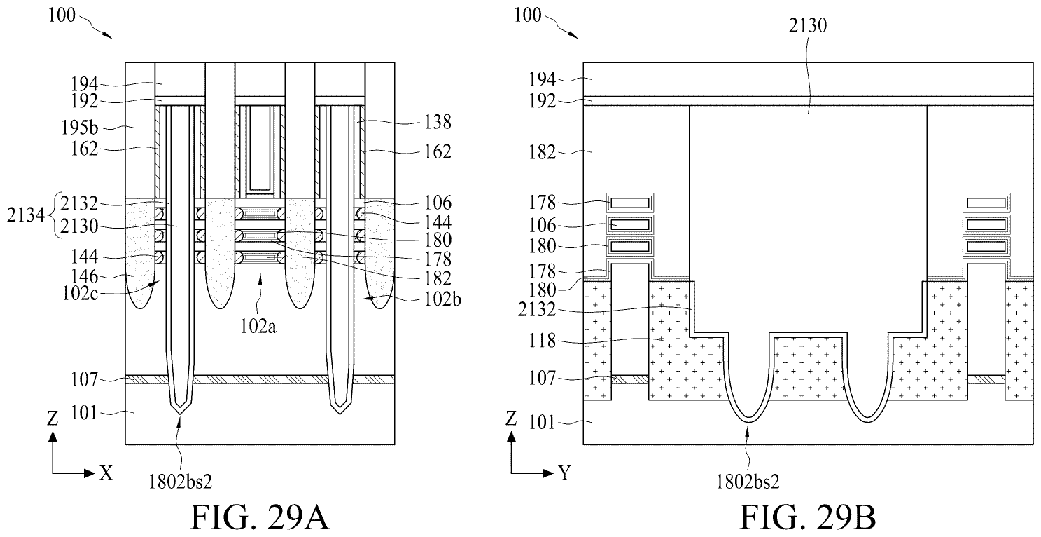

In FIGS. 29A and 29B, the openings 196 are filled with a conductive material. The openings 196 are overfilled until a predetermined height above the first ILD layer 164 is achieved. The conductive material may be made of a metal or metal nitride, such as W, Ru, Co, Cu, Ti, TiN, Ta, TaN, Mo, Ni, or combinations thereof. The conductive material may be deposited by any suitable process, such as PVD or electro-plating. A silicide layer (not shown) is formed between the epitaxial source/drain features 146 and the conductive material. The silicide layer may be made of a metal or metal alloy silicide, and the metal may include a noble metal, a refractory metal, a rare earth metal, alloys thereof, or combinations thereof.

Thereafter, a planarization operation, such as a CMP, is performed until a top surface of the second ILD layer 194 is exposed. The conductive material in the openings 196 becomes source/drain contact 195b for respective epitaxial source/drain features 146 as a result of the planarization process.

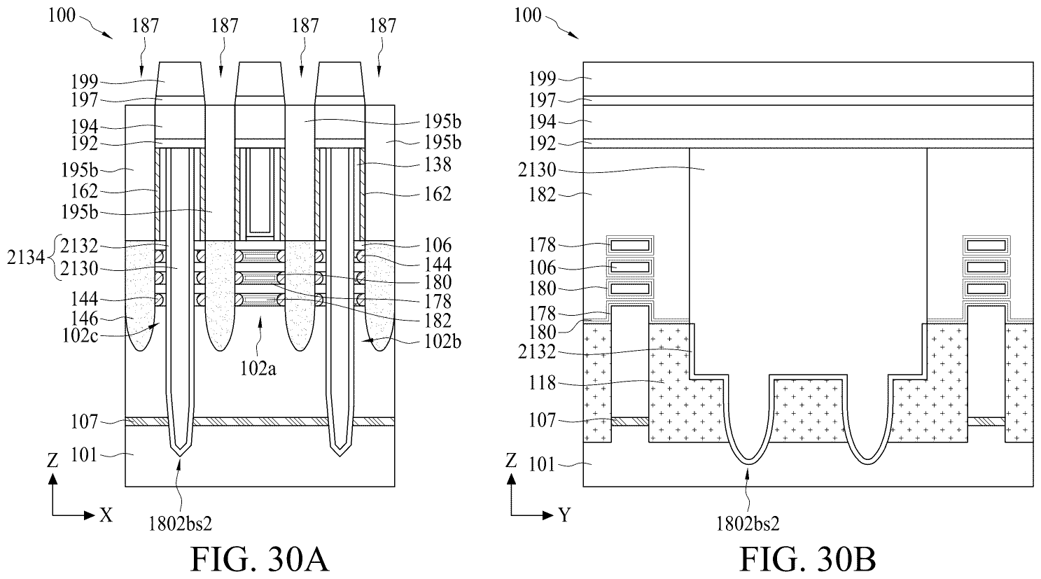

In FIGS. 30A and 30B, a second etch stop layer 197 and a third ILD layer 199 are sequentially formed on the semiconductor device structure 100. The second etch stop layer 197 and the third ILD layer 199 may include the same material as the CESL 162 and the first ILD layer 164, respectively, and may be formed in a similar fashion as discussed above. Thereafter, the second etch stop layer 197 and the third ILD layer 199 are patterned to form openings 187. The openings 187 extend through the third ILD layer 199 and the etch stop layer 197 to expose top surfaces of the source/drain contact 195b for the epitaxial source/drain features 146.

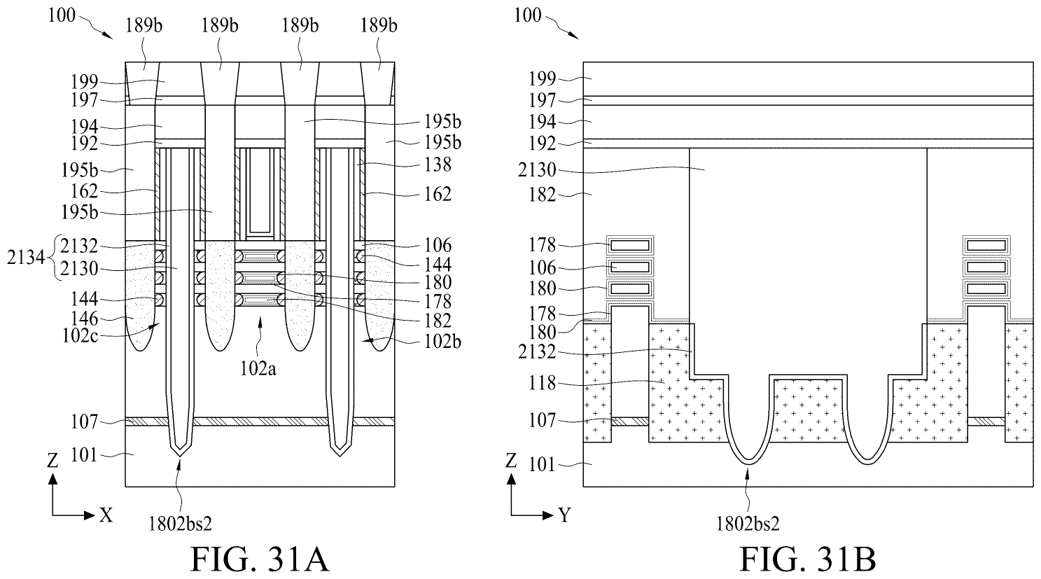

In FIGS. 31A and 31B, the openings 187 are filled with a conductive material to form contact vias 189b. The contact vias 189b electrically connect to the epitaxial source/drain features 146 through the source/drain contact 195b. The contact vias 189b may be made of the same material as the source/drain contact 195b. The conductive material may be deposited by any suitable process, such as PVD or electro-plating. Then, a planarization operation, such as a CMP, is performed until a top surface of the third ILD layer 199 is exposed.

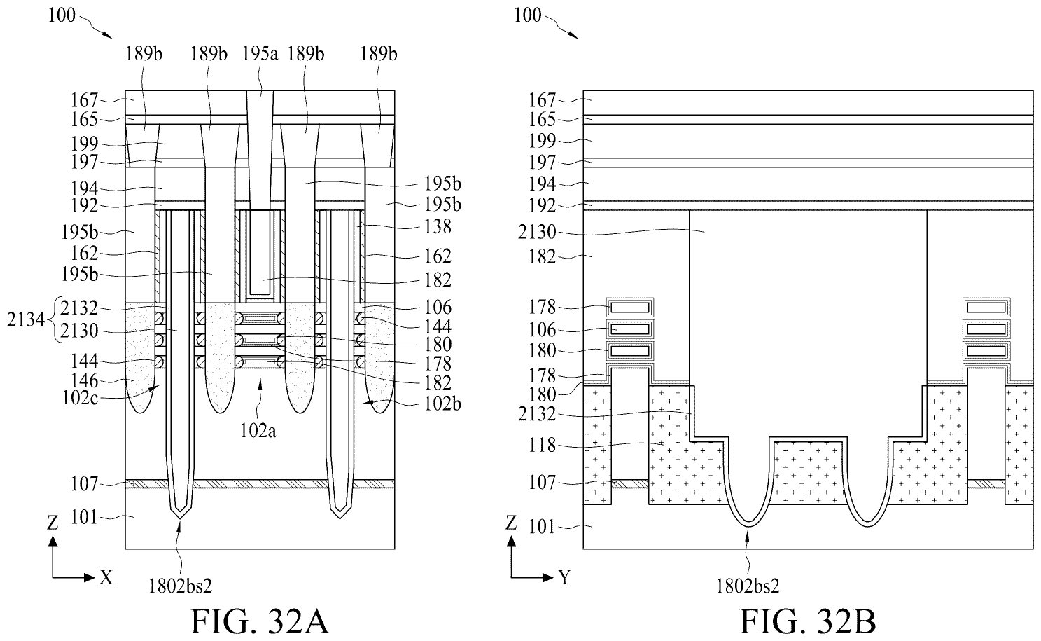

In FIGS. 32A and 32B, a third etch stop layer 165 and a fourth ILD layer 167 are sequentially formed on the semiconductor device structure 100. The third etch stop layer 165 and the fourth ILD layer 167 may include the same material as the CESL 162 and the first ILD layer 164, respectively, and may be formed in a similar fashion as discussed above. Thereafter, the third etch stop layer 165 and the fourth ILD layer 167 are patterned to form openings (only one opening is shown). The openings extend through the fourth ILD layer 167, the third etch stop layer 165, the third ILD layer 199, the second etch stop layer 197, the second ILD layer 194, and the first etch stop layer 192 to expose top surfaces of the gate electrode layer 182. The openings are then filled with a conductive material to form gate contacts 195a for the gate electrode layer 182. The gate contact 195a may serve as contact vias that electrically connects to the gate electrode layer 182. Likewise, the conductive material may be made of a metal or metal nitride, such as W, Ru, Co, Cu, Ti, TiN, Ta, TaN, Mo, Ni, or combinations thereof, and may be deposited by any suitable process, such as PVD or electro-plating.

While not shown, it is contemplated that a liner, such as the liner 175 (FIG. 28A-1) may be formed between the gate contact 195a and the etch stop layers and the ILD layers. The liner help to avoid metal diffusion or migration into the neighboring dielectrics.

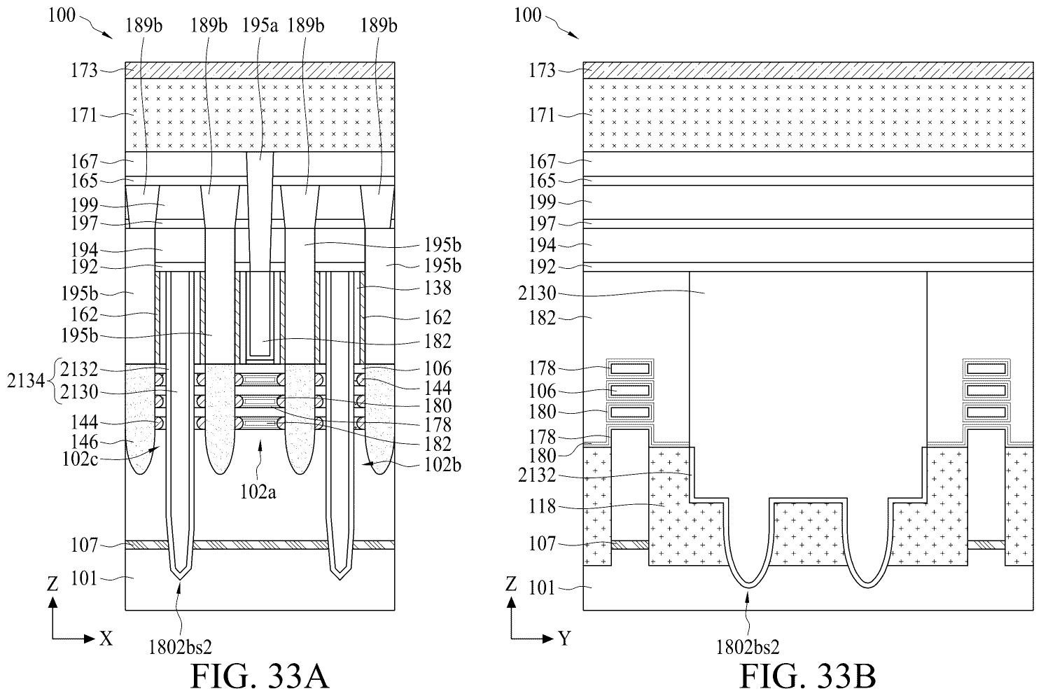

In FIGS. 33A and 33B, a front side interconnect structure 171 is formed over the third ILD layer 199 and the contact vias 189b. The front side interconnect structure 171 can be a back-end-of-line (BEOL) interconnect structure including one or more layers of dielectric material having a plurality of metal lines (not shown) and vias (not shown) embedded therein. The metal lines and vias in the front side interconnect structure 171 may be formed of copper, copper alloys, or any suitable conductive material using one or more damascene processes. The metal lines and vias provide electrical paths to the features, such as the epitaxial S/D features 146. In some embodiments, the front side interconnect structure 171 includes metal lines and vias for connecting signal lines only, but not connecting to power rails or connections to power rails. In some embodiments, the front side interconnect structure 171 includes a portion of power rails. Power rails include conductive lines connecting between the epitaxial S/D features 146 and a power source, such as VDD and VSS (GND).

After the formation of the front side interconnect structure 171, the semiconductor device structure 100 is temporarily bonded to a carrier substrate 173. The carrier substrate 173 serves to provide mechanical support for the semiconductor device structure 100 so as to facilitate backside processing of the substrate 101.

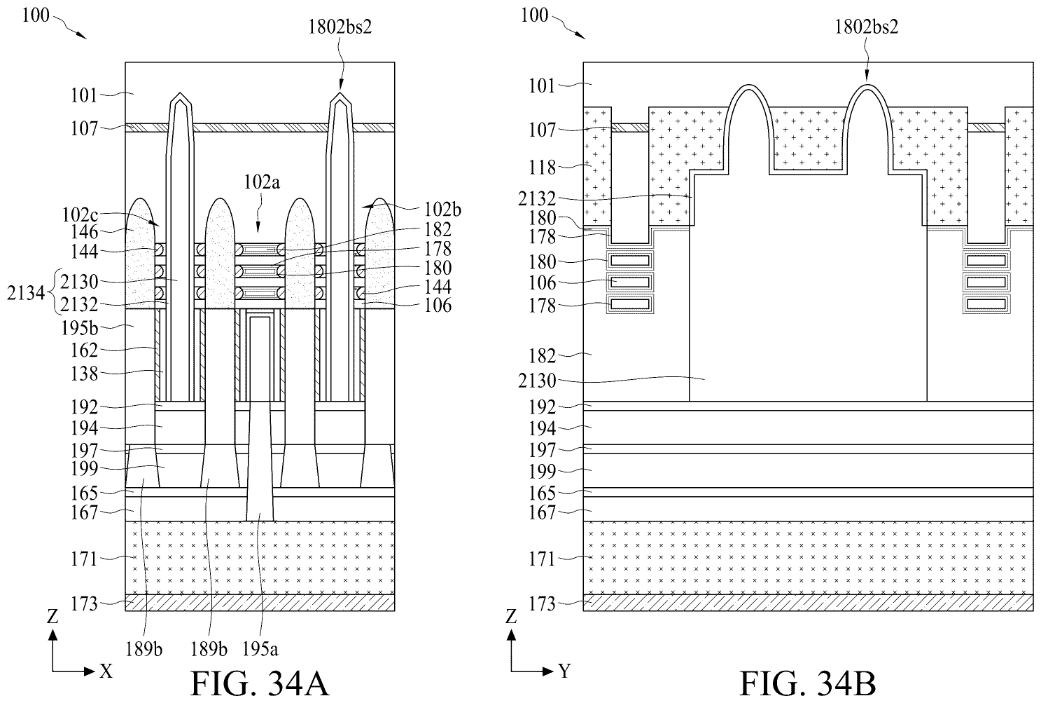

In FIGS. 34A and 34B, the semiconductor device structure 100 is flipped over so the substrate 101 as shown is over the epitaxial S/D features 146.

In FIGS. 35A and 35B, a backside grinding is performed to remove portions of the substrate 101 and the insulating material 118 until the sacrificial layer 107 is exposed. In some embodiments, the sacrificial layer 107 is also removed during the backside grinding.

In FIGS. 36A and 36B, a mask structure 3602, such as the mask structure 1302 shown in FIGS. 13A and 13B, is formed on top surfaces of the trimmed substrate 101, the dielectric material 2130, and the dielectric liner 2132. The mask structure 3602 may include a hard mask 3604 and a resist layer 3606, such as a tri-layer photoresist. An exemplary tri-layer photoresist may include a bottom layer 3608, a middle layer 3610 disposed over the bottom layer 3608, and a photoresist top layer 3612 disposed over the middle layer 3610. The photoresist top layer 3612 is then patterned to form a plurality of openings 3602a, 3062b (only two openings are shown). The openings 3602a, 3602b are in alignment with a center of respective epitaxial source/drain features 146. In some embodiments, the openings 3602a, 3602b are aligned with the epitaxial S/D feature 146 at the source region (i.e., a source terminal). In various embodiments, the openings 3602a, 3602b are aligned with a corresponding source terminal that is disposed immediately adjacent to the isolation trench structure (i.e., CPODE trench) 2134.

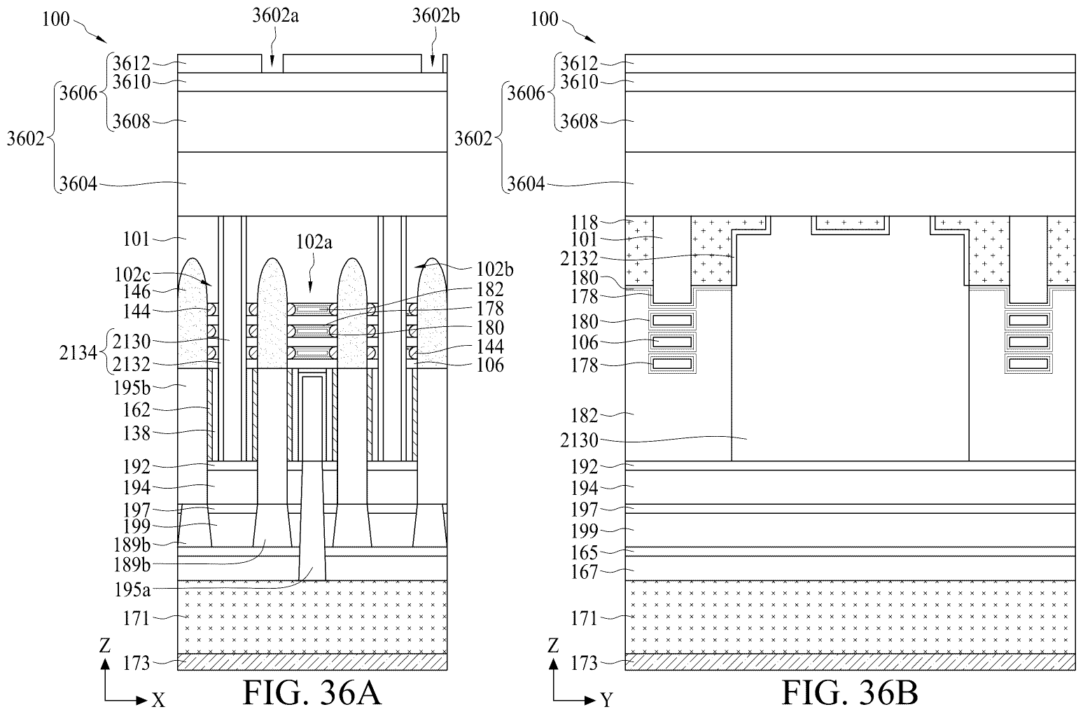

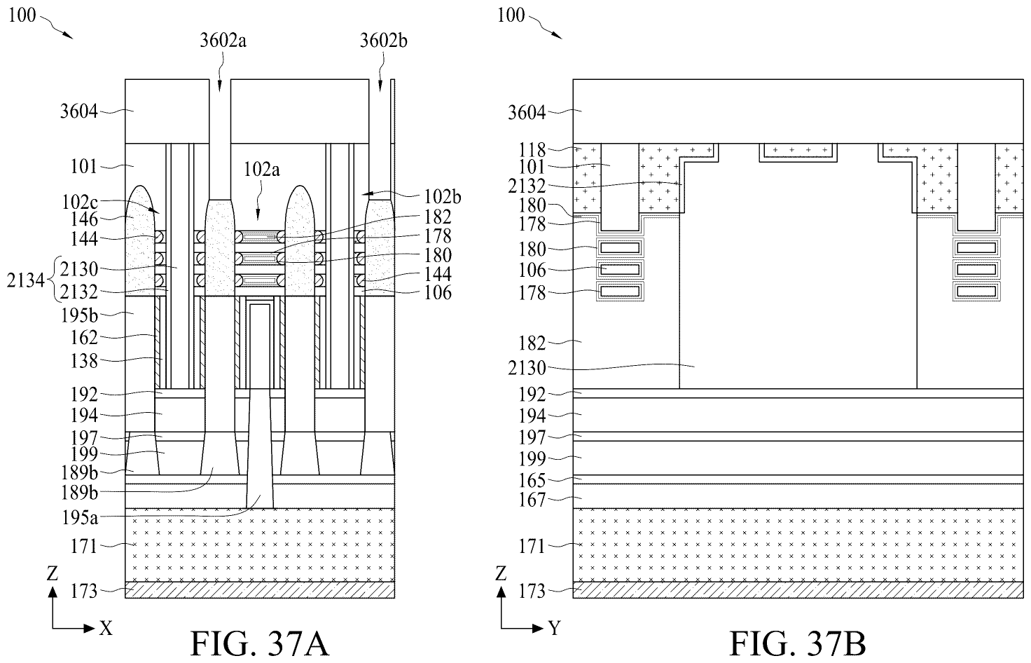

In FIGS. 37A and 37B, the patterned photoresist top layer 3612 is used as a mask to transfer the pattern (i.e., openings 3602a, 3602b) in the photoresist top layer 3612 into the middle layer 3610, the bottom layer 3608, and the mask layer 3604. The openings 3602a, 3602b are extended to expose a bottom surface of the epitaxial source/drain features 146, such as a source feature disposed immediately adjacent to the isolation trench structure 2134. The resist layer 3606 is then removed.

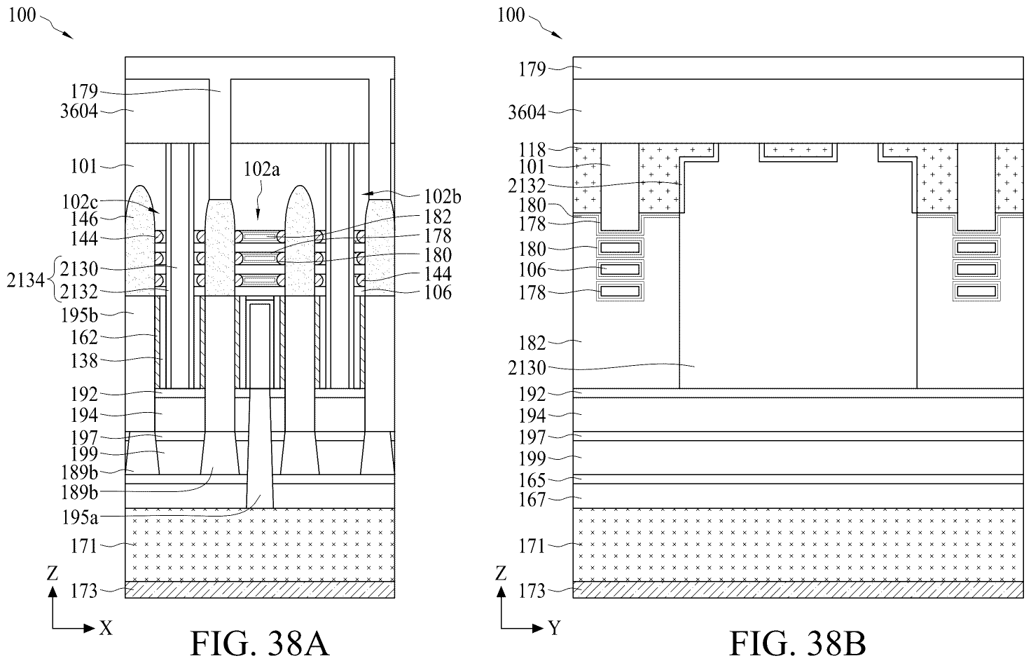

In FIGS. 38A and 38B, the openings 3602a, 3602b are filled with a conductive material 179. The conductive material may be a metal or metal nitride, such as W, Ru, Co, Cu, Ti, TiN, Ta, TaN, Mo, Ni, or combinations thereof, and may be formed by any suitable process, such as PVD or electro-plating. While not shown, in some embodiments a liner, such as the liner 175 (FIG. 28A-1) may be formed on the sidewall of the conductive material 179 to avoid metal diffusion or migration into the neighboring dielectrics.

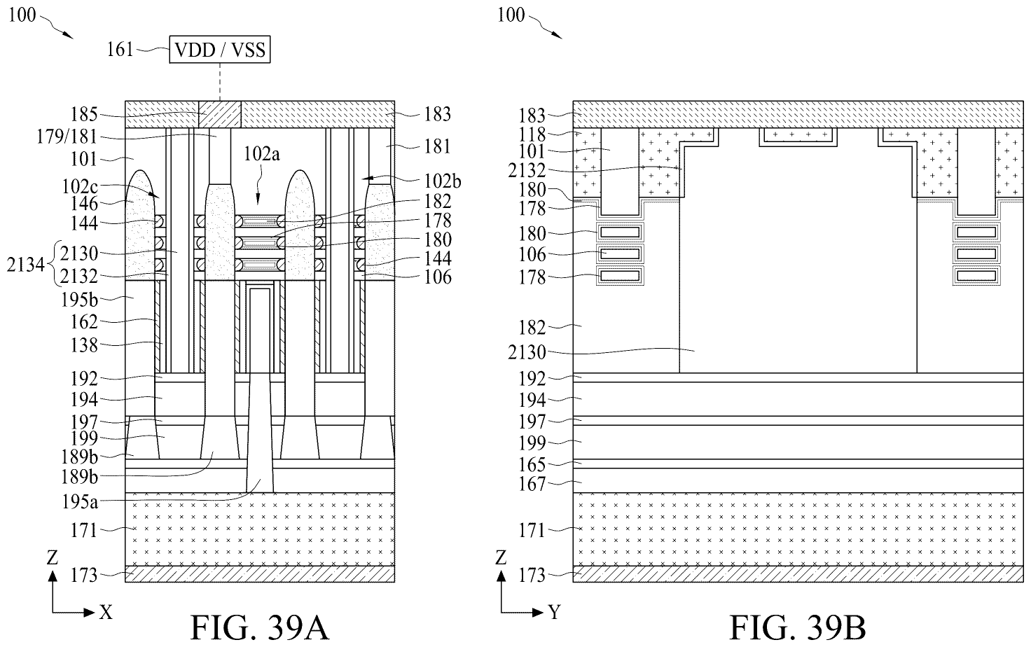

In FIGS. 39A and 39B, a planarization operation, such as a CMP, is performed on the conductive material 179. The CMP may continue until the substrate 101 is exposed. After the CMP, the bottom surfaces of the substrate 101, the dielectric material 2130, the dielectric liner 2132, and the conductive material 179 are substantially co-planar. The remaining conductive materials serve as backside via contacts 181 for the respective epitaxial source/drain features 146. In one exemplary embodiment shown in FIG. 39A, the backside via contact 181 is in contact with a source terminal disposed immediately adjacent to the isolation trench structure 2134.

A fourth ILD layer 183 may be formed over the backside of the semiconductor device structure 100. The fourth ILD 183 is in contact with the bottom surfaces of the substrate 101, the dielectric material 2130, the dielectric liner 2132, and the backside via contacts 181, which are at substantially the same elevation. One or more conductive features 185 (only one is shown) are then formed in the fourth ILD layer 183. The conductive features 185 is in electrical communication with the front side source/drain contact 195b through the backside via contacts 181 and the epitaxial S/D feature 146 (e.g., the epitaxial S/D feature 146 at the source region). The conductive feature 185 electronically connects the backside via contacts 181 to a power rail (not shown) which is to be connected to a power supply 161. Depending on the conductivity type of the device, the power supply 161 may be fed with a positive voltage (VDD) or a negative voltage (VSS) (i.e., ground or zero voltage). Having the backside via contacts 181 connected to the power rail at the backside of the semiconductor device structure 100 allows the device to be powered directly by a backside power, thereby enhancing the device performance, saving an amount of routing resources used on the front side of device, and reducing BEOL process complexity without abnormal electrical mis-connection issues.

In FIGS. 40A and 40B, the carrier substrate 173 is removed. The semiconductor device structure 100 may undergo further complementary metal oxide semiconductor (CMOS) and/or back-end-of-line (BEOL) processes on backside and/or the front side to form various features such as transistors, contacts/vias, interconnect metal layers, dielectric layers, passivation layers, etc.

The etch profile controlling semiconductor etch (e.g., the semiconductor etch, passivation, and break-through steps) discussed above with respect to FIGS. 18A-22G allows isolation trench (CPODE) structures to be formed with a straight and symmetric sidewall profile along the depth direction of the isolation trenches 2134 (i.e., non-bowing CPODE profile). Therefore, the isolation trench (CPODE) structure 2134 and the backside via contacts 181 for the epitaxial source/drain features 146 are arranged in a parallel relationship, which minimizes the risk for blocking the backside contact etch and thus facilitates the backside power rail application.

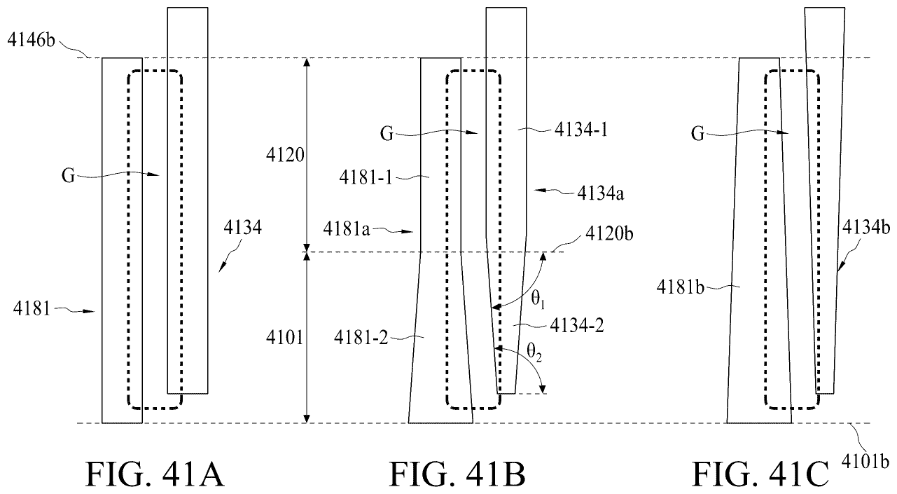

FIGS. 41A-41C illustrate a schematic view of a region 400 of the semiconductor device structure 100 in FIG. 40A showing various arrangements of an isolation trench (CPODE) structure 4134 (e.g., isolation trench structure 2134) and a backside via contact 4181 (e.g., backside via contact 181) in accordance with some embodiments. In FIG. 41A, each of the isolation trench structure 4134 and the backside via contact 4181 has a straight profile. The isolation trench structure 4134 and the backside via contact 4181 are parallelly arranged and separated from each other by a constant gap “G” along the boundaries of the isolation trench structure 4134 and the backside via contact 4181. As can be seen, a first end of each of the backside via contact 4181 and the isolation trench structure 4134, and a second end of each of the isolation trench structure 4134 and the backside via contact 4181 are at different elevations.

The embodiment of FIG. 41B is substantially identical to that of FIG. 41A except that each of a backside via contact 4181a and an isolation trench structure 4134a includes a trapezoid portion. The isolation trench structure 4134a and the backside via contact 4181a are parallelly arranged and separated from each other by a constant gap “G” along the boundaries of the isolation trench structure 4134a and the backside via contact 4181a. In some embodiments, a first portion 4181-1 of the backside via contact 4181a in contact with the bottom of the source/drain feature (e.g., epitaxial source/drain feature 146) may have a first diameter and a second portion 4181-2 of the backside via contact 4181a away from the bottom of the source/drain feature may have a second diameter greater than the first diameter. For thick wafer approaches, the first portion 4181-1 may extend in an isolation region 4120 (highly doped regime) from a first imaginary line (4146b) that is at the same elevation as the bottom of the source/drain feature (e.g., epitaxial source/drain feature 146) to a second imaginary line (4120b) that is at the same elevation as a bottom (e.g., a bottom surface 118b of the insulating material 118 shown in FIG. 40B) of the isolation region 4120. The second portion 4181-2 may extend in a well region (lightly doped regime) of a substrate 4101 (e.g., substrate 101 shown in FIG. 40A). In some embodiments, the second diameter of the second portion 4181-2 is gradually increased in a direction away from the bottom 4120b of the isolation region 4120.

Likewise, the isolation trench structure 4134a has a first portion 4134-1 extending in the isolation region 4120, and a second portion 4134-2 extending in the well region of the substrate 4101 in a direction away from the bottom 4120b of the isolation region 4120. The first portion 4134-1 has a first diameter and the second portion 4134-2 has a second diameter less than the first diameter. In some embodiments, the second diameter of the second portion 4134-2 is gradually decreased in a direction from the (e.g., a bottom surface 118b of the insulating material 118 shown in FIG. 40B) of the isolation region 4120 to an imaginary line 4101b that is at the same elevation as the bottom (e.g., a backside surface 101b of the substrate 101 shown in FIG. 40A) of the substrate, such that the upper sidewall (adjacent the bottom 4120b of the isolation region 4120) of the second portion 4134-2 of the isolation trench structure 4134a and the bottom 4120b of the isolation region 4120 define an angle θ1 that is less than 90 degrees, and the lower sidewall (adjacent a bottom of the substrate) of the second portion 4134-2 of the isolation trench structure 4134a and the bottom 4120b of the isolation region 4120 define an angle θ2 that is greater than 90 degrees. In some embodiments, the first portion 4181-1 of the backside via contact 4181a and the first portion 4134-1 of the isolation trench structure 4134a are configured to have a rectangle shape, and the second portion 4181-2 of the backside via contact 4181a and the second portion 4134-2 of the isolation trench structure 4134a are configured as two inverted-trapezoids or inverted-triangles, which can be a natural result from etching process(es) when forming the isolation trench structure 4134a and the backside via contact 4181a.

In FIG. 41C, an isolation trench structure 4134b and a backside via contact 4181b are parallelly arranged and separated from each other by a constant gap “G” along the boundaries of the isolation trench structure 4134a and the backside via contact 4181a. The embodiment of FIG. 41C is substantially identical to that of FIG. 41A except that a backside via contact 4181b and an isolation trench structure 4134b have a tapering profile, which can be a natural result from etching process(es) when forming the isolation trench structure 4134b and the backside via contact 4181b.

FIGS. 42A and 42B are cross-sectional views of the semiconductor device structure 100 showing the isolation trench structure 2134 and the backside via contact 181 arranged in accordance with the embodiment shown in FIG. 41B. In some embodiments, the isolation trench structure 2134 has a tapering profile extending over an interface defined by a bottom 118b of the insulating material 118 and the substrate 101.

Embodiments of the present disclosure provides improved etch profile control approaches for isolation trenches (e.g., CPODE) by forming a passivation layer on sidewalls of the isolation trenches to lower etch selectivity of the isolation trenches to etchants used during a directional break-through etch process, allowing the isolation trenches to be formed with a straight and symmetric sidewall profile without a bowing profile. The isolation trenches are made parallel to backside via contacts for epitaxial source/drain features to facilitate backside power rail application.

A semiconductor device structure is described. The structure includes a fin structure formed on a substrate, a source/drain feature disposed adjacent the fin structure and over the substrate, wherein a top surface of the source/drain feature and a front side of the substrate are substantially co-planar, an isolation trench extending from the front side of the substrate towards a backside of the substrate, and a backside via contact extending from the backside of the substrate towards and in contact with the source/drain feature, wherein the backside via contact and the isolation trench are parallelly arranged and separated from each other by a constant gap along boundaries of the backside via contact and the isolation trench.

Another embodiment is a method for forming a semiconductor device structure. The method includes removing a portion of a fin structure to form a first section of an isolation trench in the fin structure, passivating exposed surfaces of the first section of the isolation trench to modify an etch selectivity of the exposed surfaces to a first etchant, removing a portion of the passivated surface at a bottom of the first section of the isolation trench using the first etchant, removing a portion of a substrate to form a second section of the isolation trench using a second etchant, and filling the isolation trench with a dielectric material.

A further embodiment is a method for forming a semiconductor device structure. The method includes forming a first fin structure and a second fin structure on a first side of a substrate, each fin structure comprising a plurality of first semiconductor layers and a plurality of second semiconductor layers alternatingly stacked, forming a source/drain feature on the first side of the substrate between the first fin structure and the second fin structure, removing portions of the first semiconductor layers and the second semiconductor layers from the first fin structure to form an isolation trench having a first depth, forming a passivation layer on sidewalls and a bottom surface of the isolation trench, removing the passivation layer from the bottom surface of the isolation trench to expose a portion of the substrate, removing the passivation layer and the portion of the substrate to extend the isolation trench from the first depth to a second depth, filling the isolation trench with a dielectric material, removing the plurality of second semiconductor layers from the second fin structure; surrounding each of the first semiconductor layers of the second fin structure with a gate electrode layer, forming an opening from a second side of the substrate to expose the source/drain feature; and filling the opening with a conductive material to form a backside via contact for the source/drain feature, wherein the isolation trench and the backside via contact are parallelly arranged and separated from each other by a constant gap along boundaries of the isolation trench and the backside via contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a fin structure formed on a substrate;
a source/drain feature disposed adjacent the fin structure and over the substrate, wherein a top surface of the source/drain feature and a front side of the substrate are substantially co-planar;
an isolation trench extending from the front side of the substrate towards a backside of the substrate; and
a backside via contact extending from the backside of the substrate towards and in contact with the source/drain feature, wherein the backside via contact and the isolation trench are parallelly arranged and separated from each other by a constant gap along boundaries of the backside via contact and the isolation trench.

2. The semiconductor device structure of claim 1, wherein the isolation trench comprises a first portion having a first diameter and a second portion having a second diameter less than the first diameter.

3. The semiconductor device structure of claim 2, wherein the backside via contact comprises a first portion having a first diameter and a second portion having a second diameter greater than the first diameter of the backside via contact.

4. The semiconductor device structure of claim 2, wherein the second portion of the isolation trench has a tapering profile extending over an interface defined by an isolation region and the substrate.

5. The semiconductor device structure of claim 1, further comprising:
an interlayer dielectric disposed on the backside of the substrate, wherein a bottom surface of the isolation trench, a bottom surface of the backside via contact, and a surface of the interlayer dielectric are substantially co-planar.

6. The semiconductor device structure of claim 1, wherein the isolation trench is filled with a dielectric material and a dielectric liner disposed between the dielectric material and sidewalls of the isolation trench.

7. The semiconductor device structure of claim 1, wherein the fin structure comprises a plurality of first semiconductor layers surrounded by a gate electrode layer, the first semiconductor layers forming nanosheet channels.

8. A method for forming a semiconductor device structure, comprising:
removing a portion of a fin structure to form a first section of an isolation trench in the fin structure;
passivating exposed surfaces of the first section of the isolation trench to modify an etch selectivity of the exposed surfaces to a first etchant;
removing a portion of the passivated surface at a bottom of the first section of the isolation trench using the first etchant;
removing a portion of a substrate to form a second section of the isolation trench using a second etchant; and
filling the isolation trench with a dielectric material.

9. The method of claim 8, wherein passivating the exposed surfaces comprises forming a passivation layer on the exposed surfaces of the first section of the isolation trench using a gas mixture comprising a silicon-containing precursor and an oxygen-containing precursor.

10. The method of claim 9, wherein the gas mixture further comprises a hydrogen halide, and the passivation layer is a bromine-containing or hydrogen-containing silicon monoxide (SiO), silicon dioxide (SiO2), or silicon nitride (SixNy) in an amorphous phase.

11. The method of claim 8, wherein the first etchant comprises a bromine-based etch chemistry and an oxygen-based chemistry.

12. The method of claim 8, further comprising:
applying a first bias voltage to a substrate pedestal during the removal of the portion of the substrate; and
applying a second bias voltage to the substrate pedestal during the removal of the portion of the passivated surface, wherein the second bias voltage is greater than the first bias voltage.

13. The method of claim 8, wherein the first section of the isolation trench has a first diameter, and the second section of the isolation trench has a second diameter substantially the same as the first diameter.

14. The method of claim 8, wherein passivating the exposed surfaces and removing the portion of the passivated surface are performed in the same processing chamber.

15. The method of claim 8, further comprising:
repeating the passivating and removing steps in a cyclic etch process until the isolation trench reaches a predetermined depth.

16. A method for forming a semiconductor device structure, comprising:
forming a first fin structure and a second fin structure on a first side of a substrate, each fin structure comprising a plurality of first semiconductor layers and a plurality of second semiconductor layers alternatingly stacked;
forming a source/drain feature on the first side of the substrate between the first fin structure and the second fin structure;
removing portions of the first semiconductor layers and the second semiconductor layers from the first fin structure to form an isolation trench having a first depth;
forming a passivation layer on sidewalls and a bottom surface of the isolation trench;
removing the passivation layer from the bottom surface of the isolation trench to expose a portion of the substrate;
removing the passivation layer and the portion of the substrate to extend the isolation trench from the first depth to a second depth;
filling the isolation trench with a dielectric material;
removing the plurality of second semiconductor layers from the second fin structure; surrounding each of the first semiconductor layers of the second fin structure with a gate electrode layer;
forming an opening from a second side of the substrate to expose the source/drain feature; and filling the opening with a conductive material to form a backside via contact for the source/drain feature, wherein the isolation trench and the backside via contact are parallelly arranged and separated from each other by a constant gap along boundaries of the isolation trench and the backside via contact.

17. The method of claim 16, further comprising:
repeating the steps of forming the passivation layer and removing the passivation layer and the portion of the substrate until the isolation trench reaches a predetermined depth.

18. The method of claim 16, wherein forming the passivation layer comprises using a gas mixture comprising a silicon-containing precursor, an oxygen-containing precursor, and a hydrogen halide.

19. The method of claim 16, wherein the isolation trench is formed with a straight and symmetric sidewall profile.

20. The method of claim 16, further comprising:
forming a front side interconnect structure over the source/drain feature, wherein the front side interconnect structure includes metal lines and vias for signal lines, and the backside via contact connects to a power rail.
